(19) United States
(12) Patent Application Publication
(10) Pub. No.: US 2025/0372491 A1
(43) Pub. Date: Dec. 4, 2025

(54) SEMICONDUCTOR PACKAGE AND METHOD OF FORMING THE SAME

(71) Applicant: Taiwan Semiconductor Manufacturing Company, Ltd., Hsinchu (TW)

(72) Inventors: Wei-Yu Chen, Taipei City (TW); Cheng-Shiuan Wong, Hsinchu City (TW); Chao-Wei Chiu, Hsinchu City (TW); Hsin Liang Chen, New Taipei City (TW); Hsuan-Ting Kuo, Taichung City (TW); Hao-Jan Pei, Hsinchu (TW); Hsiu-Jen Lin, Hsinchu County (TW); Chia-Shen Cheng, Hsinchu County (TW); Cheng-Ting Chen, Taichung City (TW); Hao-Jan Shih, Hsinchu (TW); Chih-Chiang Tsao, Taoyuan City (TW)

(73) Assignee: Taiwan Semiconductor Manufacturing Company, Ltd., Hsinchu (TW)

(21) Appl. No.: 18/677,901

(22) Filed: May 30, 2024

(51) Int. Cl. H01L 23/498; H01L 21/56; H01L 23/00; H01L 23/31; H01L 25/10

(52) U.S. Cl. CPC H01L 23/49833; H01L 21/56; H01L 23/3157; H01L 24/16; H01L 24/32; H01L 24/73; H01L 25/105; H01L 24/08; H01L 2224/08225; H01L 2224/16225; H01L 2224/32225; H01L 2224/73204; H01L 2924/1815

(57) ABSTRACT

A semiconductor package and a method of forming the same are provided. The semiconductor package includes a substrate, a first interposer, a second interposer, a first die, a second die and a bridge die. The first interposer and the second interposer are arranged side by side over the substrate. The first die is disposed on the first interposer. The second die is disposed on the second interposer. The bridge die is disposed on and electrically connected between the first interposer and the second interposer. The first die and the second die are electrically connected to each other through the first interposer, the second interposer and the bridge die.

### BACKGROUND

Recently the demand for large sized interposer is increased to connect various devices for multi-functions and applications. As the increasing size of the interposer, it may be challenging to joint the large sized interposer on the substrate, so that the yield and the utilization of wafer may be affected.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A to 1J are schematic sectional views at various stages in a method of fabricating a sub-package in accordance with some embodiments of the present disclosure.

FIGS. 2A to 2C are schematic sectional views at various stages in a method of fabricating a semiconductor package in accordance with some embodiments of the present disclosure.

FIG. 3A is an enlargement view of an alternative embodiment of FIG. 2B in accordance with some embodiments of the present disclosure.

FIG. 3B is an enlargement view of an alternative embodiment of FIG. 2C in accordance with some embodiments of the present disclosure.

FIG. 4A is a top view of an embodiment of FIG. 2C in accordance with some embodiments of the present disclosure.

FIG. 4B is a top view of an embodiment of FIG. 2C in accordance with some embodiments of the present disclosure.

FIGS. 5A to 5D are schematic sectional views at various stages in a method of fabricating a semiconductor package in accordance with some embodiments of the present disclosure.

FIG. 6A is an enlargement view of an alternative embodiment of FIG. 5C in accordance with some embodiments of the present disclosure.

FIG. 6B is a top view of an embodiment of cavity in FIG. 5C or FIG. 6A in accordance with some embodiments of the present disclosure.

FIG. 6C is an enlargement view of an alternative embodiment of FIG. 5D in accordance with some embodiments of the present disclosure.

FIGS. 7A to 7D are schematic sectional views at various stages in a method of fabricating a semiconductor package in accordance with some embodiments of the present disclosure.

FIG. 8A is an enlargement view of an alternative embodiment of FIG. 7C in accordance with some embodiments of the present disclosure.

FIG. 8B is an enlargement view of an alternative embodiment of FIG. 7D in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around”, “about”, “approximately”, or “substantially” shall generally mean within 20 percent, or within 10 percent, or within 5 percent of a given value or range. Numerical quantities given herein are approximate, meaning that the term “around”, “about”, “approximately”, or “substantially” can be inferred if not expressly stated.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

According to embodiments of the present disclosure, a semiconductor package is described. The semiconductor package includes a first interposer, a second interposer and a bridge die connecting between the first interposer and the second interposer, so that a first die on the first interposer can be electrically connected to a second die on the second interposer through the bridge die. By connecting the first interposer and the second interposer through the bridge die, a large-sized interposer can be easily formed and jointed on the substrate, such that the wafer yield and utilization can be improved.

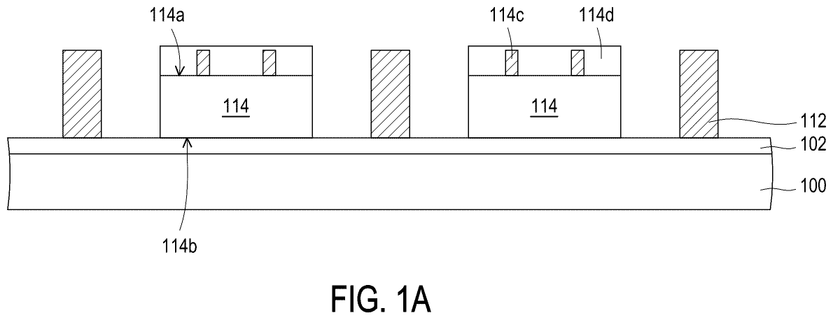

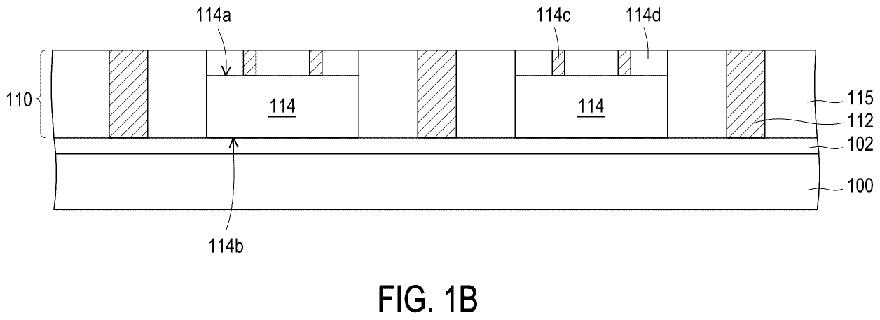

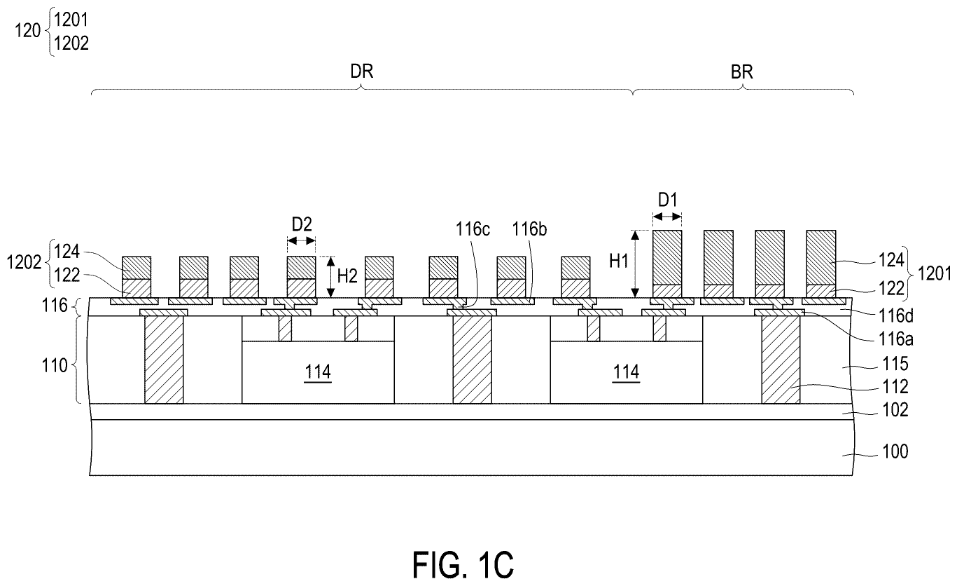

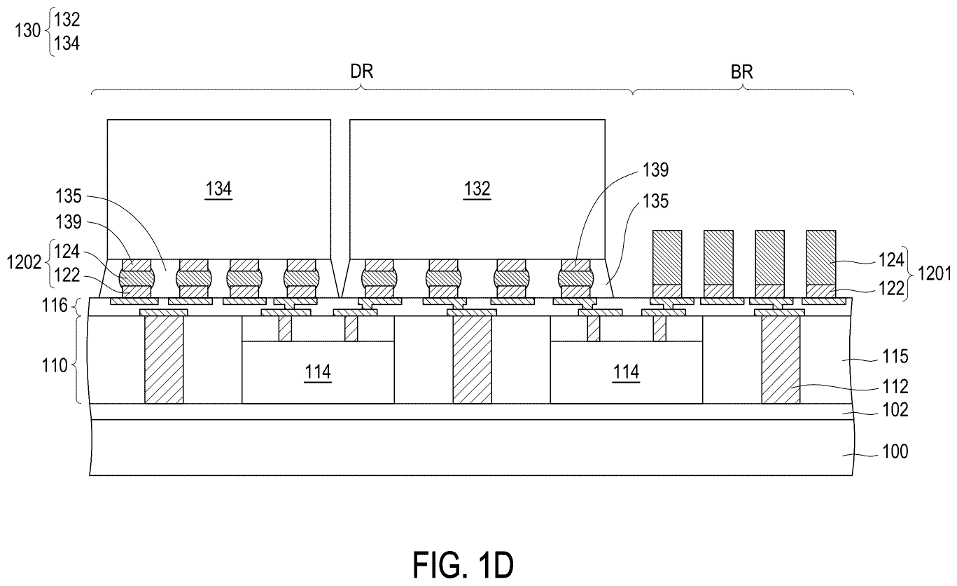

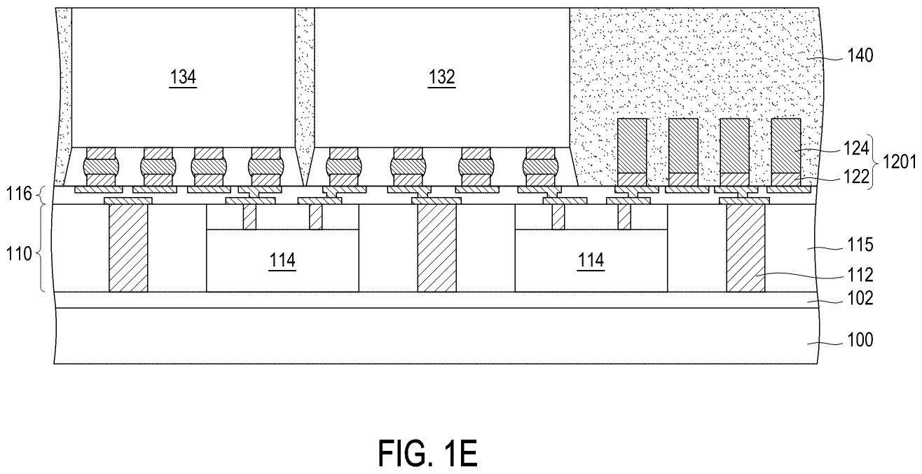

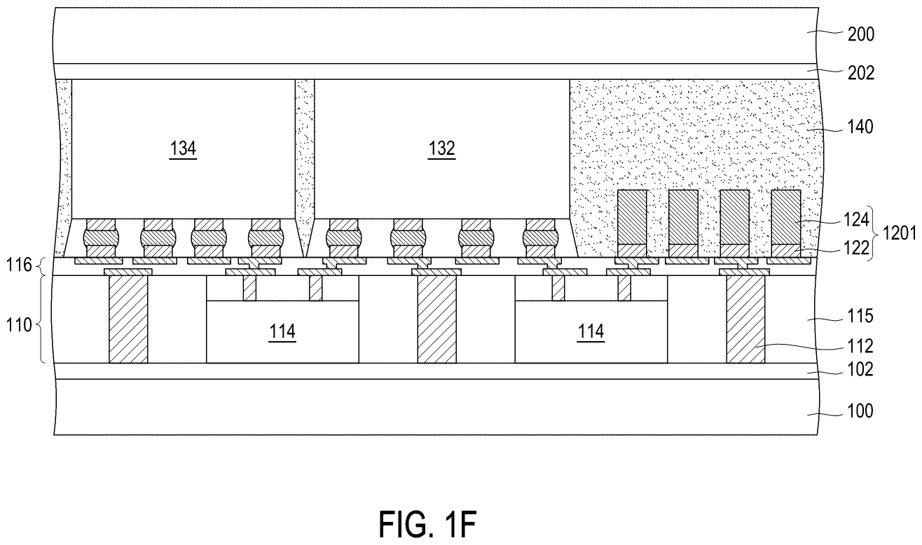

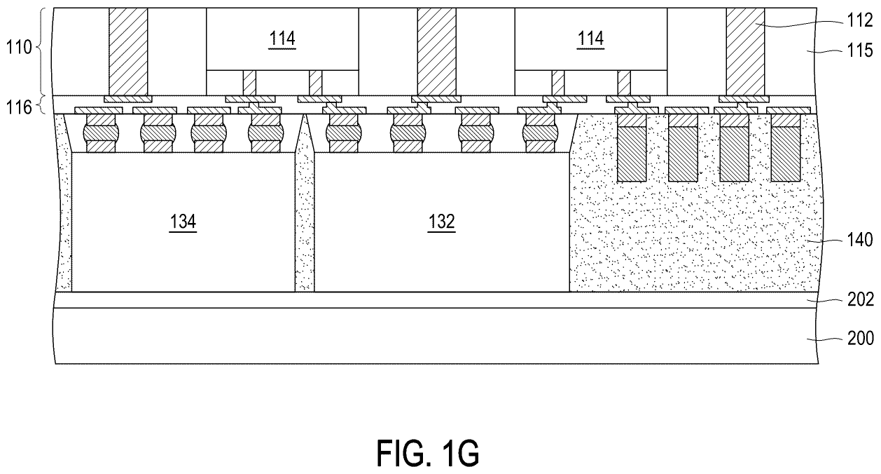

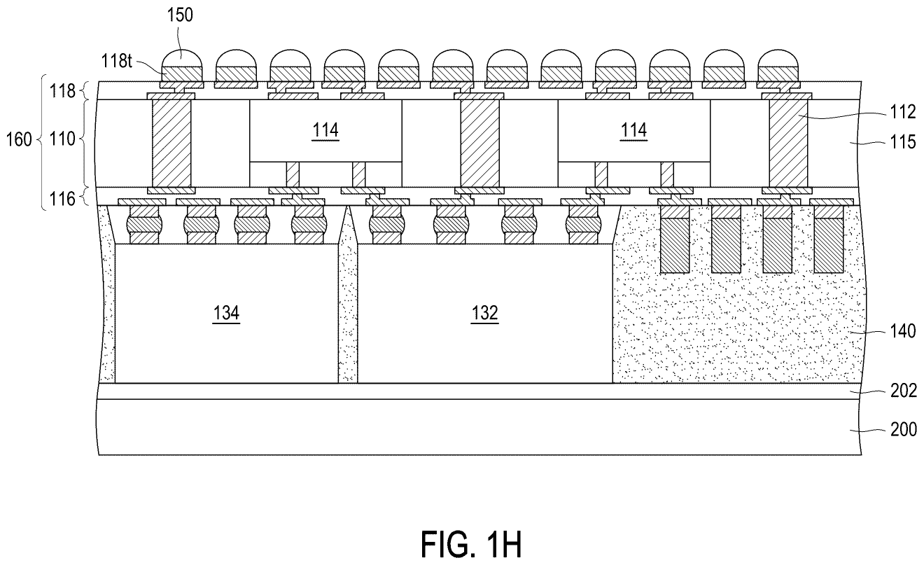

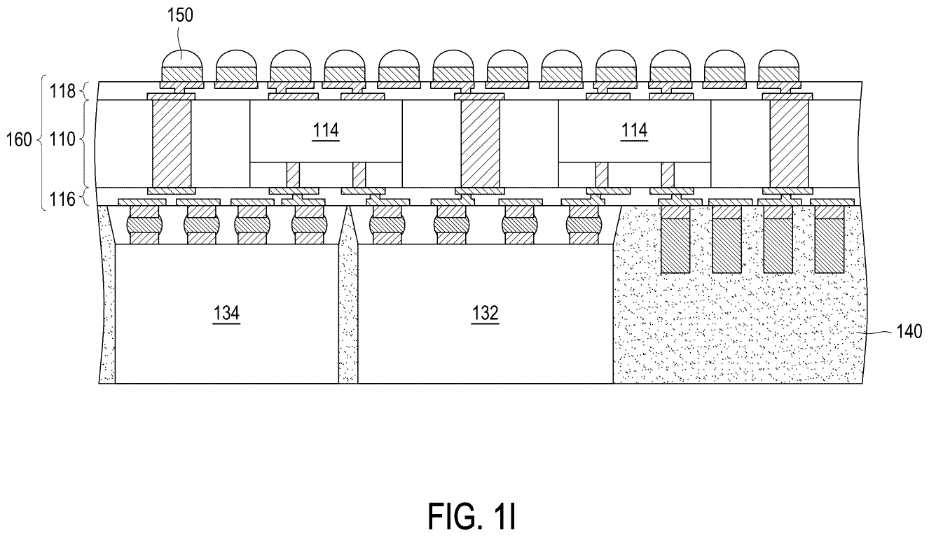

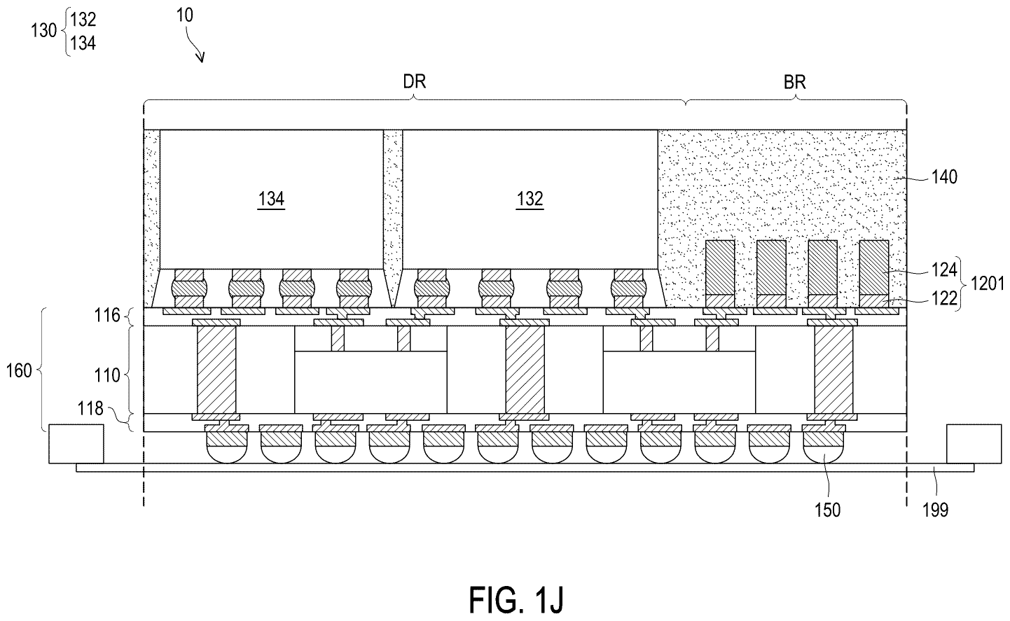

FIGS. 1A to 1J are schematic sectional views at various stages in a method of fabricating a sub-package 10 in accordance with some embodiments of the present disclosure.

Referring to FIG. 1A, a carrier 100 is provided. The carrier 100 may be any suitable substrate that provides (during intermediary operations of the fabrication process) mechanical support for the layers over the carrier 100. For example, the carrier 100 may be a glass carrier, a ceramic carrier, an organic carrier, a silicon wafer or the like, which is not limited. An adhesive layer 102 may be formed on the carrier 100. In some embodiments, the adhesive layer 102 may be film over wire (FOW), die attach film, or other suitable adhesive material laminated on the carrier 100. In some embodiments, the adhesive layer 102 may be a release layer to easily release the carrier 100 from the structure formed thereon. For example, the release layer may be a Light-To-Heat-Conversion (LTHC) layer which is capable of being decomposed under the heat of light/radiation (such as laser).

Still referring to FIG. 1A, conductive pillars 112 are formed over the carrier 100. For example, a seed layer (not shown) may be formed over the adhesive layer 102 by physical vapor deposition (PVD), chemical vapor deposition (CVD), atomic layer deposition (ALD), the like, or a combination thereof. Then a photoresist (not shown) is formed on the seed layer and patterned to form openings (not shown) exposing the seed layer. A conductive material (not shown) may be formed in the openings by physical vapor deposition (PVD), chemical vapor deposition (CVD), atomic layer deposition (ALD), electrical plating, the like, or a combination thereof. Then, the patterned photoresist and the seed layer under the patterned photoresist is removed by, for example, ashing process, etching process or other suitable removal process, to form the conductive pillars 112. In some embodiments, the seed layer, the conductive material and the conductive pillar may be or include, for example, tungsten (W), cobalt (Co), copper (Cu), aluminum (Al), nickel (Ni), ruthenium (Ru), gold (Au), silver (Ag), molybdenum (Mo), manganese (Mg), zirconium (Zr), alloys of the aforementioned metal, a combination thereof, or other suitable conductive materials.

Still referring to FIG. 1A, placing semiconductor dies 114 over the carrier 100. The semiconductor dies 114 may each include conductive terminals 114c and a protective layer 114d laterally encapsulating the conductive terminals 114c. The protective layer 114d may also cover the top surfaces of the conductive terminals 114c. However, the protective layer 114d is optional, and thus in other embodiments, the semiconductor die 114 may not include the protective layer 114d. In some embodiments, the conductive terminals 114c may be formed on a front side 114a of the semiconductor die 114 for external connection. A backside 114b of the semiconductor die 114 opposite to the front side 114a may be attached to the adhesive layer 102. In some embodiments, the semiconductor dies 114 may each include a semiconductor substrate (not shown) and an interconnect structure (e.g., multilayer interconnect structures, through silicon vias, and etc.) (not shown) formed on or in the semiconductor substrate to provide local silicon interconnect. The conductive terminals 114c may be electrically connected with the interconnect structure. Please note that the number and arrangement of the semiconductor dies 114 and the conductive pillars 112 are not limited to the drawings of the embodiments, and may be selected and designated based on the demand and design requirements.

Referring to FIG. 1B, an encapsulant 115 is formed over the carrier 100 and laterally encapsulates the conductive pillars 112 and the semiconductor dies 114. For example, a molding material (not shown) may be formed over the carrier 100 to cover top surfaces of the conductive pillars 112 and top surfaces of the semiconductor dies 114, and then a planarization process (such as chemical mechanical polishing (CMP), grinding process or other suitable process) is performed to remove a portion of the molding material to expose top surfaces of the conductive pillars 112 and top surfaces of the conductive terminals 114c of the semiconductor dies 114. In some embodiments, the molding material is formed by a suitable fabrication technique such as molding, spin-coating, lamination, deposition, or similar processes. In some embodiments, the molding material is made of a molding compound, a polymer, an epoxy, silicon oxide filler material, the like, or a combination thereof. The conductive pillars 112, the semiconductor dies 114 and the encapsulant 115 may be collectively referred to an interposer substrate 110.

Referring to FIG. 1C, a redistribution structure 116 is formed on the interposer substrate 110. The redistribution structure 116 may include redistribution layers 116a and 116b and a dielectric layer 116d stacked alternatively and conductive vias 116c between the adjacent redistribution layers 116a and 116b to physically and electrically connect the adjacent redistribution layers 116a and 116b. For example, a conductive material layer (not shown) may be formed on the encapsulant 115 and then patterned to form the redistribution layer 116a. Then a dielectric material layer may be formed on the redistribution layer 116a by and then patterned to form the dielectric layer 116d. The dielectric layer 116d may have corresponding openings for subsequent connection purpose. Then, a conductive material layer (not shown) may be formed on the dielectric layer 116d and in the openings and then patterned to form the redistribution layer 116b on the dielectric layer 116d and the conductive vias 116c in the openings. In some embodiments, the conductive material layer may be formed by, for example, CVD, PVD, ALD, sputtering, electrochemical plating, electroless plating, some other deposition process, or a combination of the foregoing. In some embodiments, a process for patterning the conductive material layer includes forming a mask layer (e.g., positive/negative photoresist, a hardmask, and etc.) on the conductive material layer, and performing an etching process (e.g., wet etching process, dry etching process, reactive ion etching (RIE) process, etc.) to the conductive material to remove the unmasked portion of the conductive material layer, and stripping away the mask layer. In some embodiments, the dielectric material layer may be formed by, for example, chemical vapor deposition (CVD), physical vapor deposition (PVD), atomic layer deposition (ALD), spin-coating, some other deposition process, or a combination of the foregoing. In some embodiments, the dielectric material layer may be patterned via a lithography process, such as photolithography, extreme ultraviolet lithography, or the like.

In some embodiments, the dielectric layer 116d may include an oxide, such as silicon oxide or silicon oxynitride; a nitride, silicon nitride or silicon carbon nitride; a polymer-based dielectric material, such as polyimide, epoxy resin, acrylic resin, phenol resin, benzocyclobutene (BCB), polybenzooxazole (PBO), and/or any other suitable polymer-based dielectric material. The redistribution layers 116a and 116b and the conductive via 116c may be or include, for example, tungsten (W), cobalt (Co), copper (Cu), aluminum (Al), nickel (Ni), ruthenium (Ru), gold (Au), silver (Ag), molybdenum (Mo), manganese (Mg), zirconium (Zr), alloys of the aforementioned metal, a combination thereof, or other suitable conductive materials. Please note that the number and arrangement of the redistribution layers in the redistribution structure 116 are not limited to the drawings of the embodiments, and may be selected and designated based on the demand and design requirements.

In some embodiments, a passivation layer (not shown) may be formed on the topmost redistribution layer (that is, redistribution layer 116b) of the redistribution structure 116 by, for example, chemical vapor deposition (CVD), physical vapor deposition (PVD), atomic layer deposition (ALD), spin-coating, some other deposition process, or a combination of the foregoing.

Still referring to FIG. 1C, conductive connectors 120 are formed over the redistribution structure 116 and electrically connected with the topmost redistribution layer (that is, redistribution layer 116b) of the redistribution structure 116. In some embodiments, the conductive connectors 120 each include a conductive post 122 and a solder cap 124 disposed on the conductive post 122. The conductive posts 122 may include gold bump, copper bump, copper post, copper pillars, or the like or combinations thereof. The conductive posts 122 may be formed by, for example, forming a photoresist (not shown) over the passivation layer, patterning the photoresist to form openings (not shown), then forming the conductive material of the conductive posts 122 in the openings of the photoresist, and stripping away the photoresist. The solder caps 124 may include tin, or other suitable materials. The solder caps 124 may be formed by electroplating, printing, solder transfer, ball placement, combinations thereof or other suitable method. In other embodiments, the conductive connectors 120 may include the conductive post 122 and may be free of the solder cap 124.

In some embodiments, the interposer substrate 110 may have a device region DR for disposing a device in the subsequent process and a bridge region BR for disposing a bridge die in the subsequent process. The conductive connectors 120 may include first conductive connectors 1201 in the bridge region BR, and second conductive connectors 1202 in the device region DR. The first conductive connectors 1201 and the second conductive connectors 1202 may be formed in different process steps to have different dimensions. For example, the second conductive connectors 1202 may be formed first and then the first conductive connectors 1201 may be formed, or vice versa. In some embodiments, a first photoresist (not shown) is formed over the device region DR and the bridge region BR, and then the first photoresist is patterned to form openings (not shown) in the device region DR. Subsequently, a first electroplating process is performed to form the conductive posts 122 in the openings of the first photoresist and then a second electroplating process is performed to form the solder caps 124 on the conductive posts 122, so that the second conductive connectors 1202 in the device region DR are formed. Then the first photoresist is removed. Next, a second photoresist (not shown) is formed over the device region DR and the bridge region BR as well as covers the second conductive connectors 1202, and then the second photoresist is patterned to form openings (not shown) in the bridge region BR. Subsequently, a third electroplating process is performed to form the conductive posts 122 in the openings of the second photoresist and then a second electroplating process is performed to form the solder caps 124 on the conductive posts 122, so that the first conductive connectors 1201 in the bridge region BR are formed. Then the second photoresist is removed. By adjusting the process parameters (such as electroplating time, current density, electroplating temperature, electroplating solution and so on) of the first electroplating process, the second electroplating process, the third electroplating process and the fourth electroplating process, the conductive posts 122 and the solder caps 124 of the first conductive connectors 1201 and the second conductive connectors 1202 may be formed to have different dimensions based on the actual demands.

In an embodiment where a dimension (such as a height, a diameter, a width or the like) of the first conductive connectors 1201 is different from that of the second conductive connectors 1202, a height H1 of the first conductive connectors 1201 may be greater than a height H2 of the second conductive connectors 1202, and a diameter D1 of the first conductive connectors 1201 may be greater than a diameter D2 of the second conductive connectors 1202. However, the disclosure is not limited. The number, size and arrangement of the first conductive connectors 1201 and the second conductive connectors 1202 may be selected and designated based on the demand and design requirements.

In some embodiments, before forming the conductive connectors 120, an under-bump metallization (UBM) layer (not shown) may be formed on the passivation layer and extends through the passivation layer to electrically connect with the topmost redistribution layer (that is, redistribution layer 116b) of the redistribution structure 116, so that the conductive connectors 120 may be electrically connected to the redistribution layer 116b through the UBM layer and the adhesion between the conductive connectors 120 and the redistribution layer 116b could be improved.

Referring to FIG. 1D, a plurality of dies 130 (such as die 132 and die 134) is disposed in the device region DR, and the dies 132 and 134 are physically and electrically connected to the second conductive connectors 1202, and an underfill 135 is formed in a gap between each of the dies 130 and the first redistribution structure 116 and laterally encapsulates the second conductive connectors 1202.

The plurality of dies 130 may respectively be an application-specific integrated circuit (ASIC) chip, an System on Chip (SoC), an analog chip, a sensor chip, a wireless and radio frequency chip, a voltage regulator chip, a logic die such as a Central Processing Unit (CPU) die, a Micro Control Unit (MCU) die, a BaseBand (BB) die, an Application processor (AP) die, or a memory chip such as a Dynamic Random Access Memory (DRAM) die, a Static Random Access Memory (SRAM) die, or a high bandwidth memory (HBM) chip, or other suitable types of die. In some embodiments, the die 132 and the die 134 are arranged side by side, the die 132 is an SoC, and the die 134 is an HBM chip, but the disclosure is not limited thereto. Please note that the number and arrangement of the dies 132 and 134 are not limited to the drawings of the embodiments, and may be selected and designated based on the demand and design requirements.

In some embodiments, each of the dies 130 (such as the dies 132 and 134) has conductive connectors 139 for external connection, which are bonded to the third conductive connectors 1202 to electrically connect to the redistribution structure 116. In some embodiments, the dies 132 and 134 may be electrically connected to each other through the semiconductor die 114.

In some embodiments, the underfill 135 may be formed by an underfill dispensing process, a capillary flow process, or any other suitable method. The underfill 135 may be a material such as a molding compound, an epoxy, an underfill compound, a molding underfill (MUF), a resin, or the like. In some embodiments, the underfill 135 distributed under the die 132 may be in contact with the underfill 135 distributed under the die 134.

Referring to FIG. 1E, an insulating encapsulant 140 (e.g. a gap filling material) is formed over the redistribution structure 116 and laterally encapsulates the dies 130 and the first conductive connectors 1201. For example, an insulating material (not shown) may be formed over the first redistribution structure 116 and cover the dies 130 by, for example, chemical vapor deposition (CVD), physical vapor deposition (PVD), atomic layer deposition (ALD), some other deposition process, or a combination of the foregoing. Then a planarization process (such as chemical mechanical polishing (CMP), grinding process or the like) is performed to remove a portion of the insulating material until a top surface of the dies 130 is exposed.

Referring to FIG. 1F, a carrier 200 is bonded to the dies 130 and the insulating encapsulant 140 by an adhesive layer 202. The carrier 200 and the adhesive layer 202 may be similar to the aforementioned carrier 100 and adhesive layer 102.

Referring to FIG. 1G, the resulted structure of FIG. 1F is flipped and the carrier 100 is debonded. A planarization process (such as chemical mechanical polishing (CMP), grinding process or the like) may be performed to expose the conductive pillars 112, the semiconductor dies 114, and the encapsulant 115.

Referring to FIG. 1H, a redistribution structure 118 is formed on the interposer substrate 110, and conductive terminals 150 are formed over the redistribution structure 118. The redistribution structure 118 may include redistribution layers and dielectric layer stacked alternatively. The forming of the second redistribution structure 118 may be similar to the forming of the first redistribution structure 116. In some embodiments, the conductive terminals 150 are formed on contact pads 118t of the second redistribution structure 118. The contact pads 118t may be the topmost redistribution layer in the redistribution structure 118. In some embodiments, an UBM layer (not shown) may be formed between the contact pads 118t and the conductive terminals 150. In some embodiments, the conductive terminals 150 may be ball grid array (BGA) connectors, solder balls, controlled collapse chip connection (C4) bumps, or a combination thereof. In some embodiments, the material of the conductive terminals 150 includes copper, aluminum, lead-free alloys (e.g., gold, tin, silver, aluminum, or copper alloys) or lead alloys (e.g., lead-tin alloys). The conductive terminals 150 may be formed by a suitable process such as evaporation, plating, ball dropping, screen printing and reflow process, a ball mounting process, a C4 process or other suitable process. The interposer substrate 110, the redistribution structure 116, the conductive connectors 120 and the redistribution structure 118 may be collectively referred to an interposer 160.

Referring to FIG. 1I, the carrier 200 is debonded so that the dies 130 and the insulating encapsulant 140 are exposed.

Referring to FIG. 1J, the structure of FIG. 1I is flipped and placed on a frame 199, where the conductive terminals 150 are in contact with the frame 199. Then a singulation process is performed to form a plurality of sub-packages 10. Each sub-packages 10 may include an interposer 160, dies 130 disposed over the interposer 160 and an insulating encapsulant 140 disposed over the interposer 160 and encapsulating the dies 130.

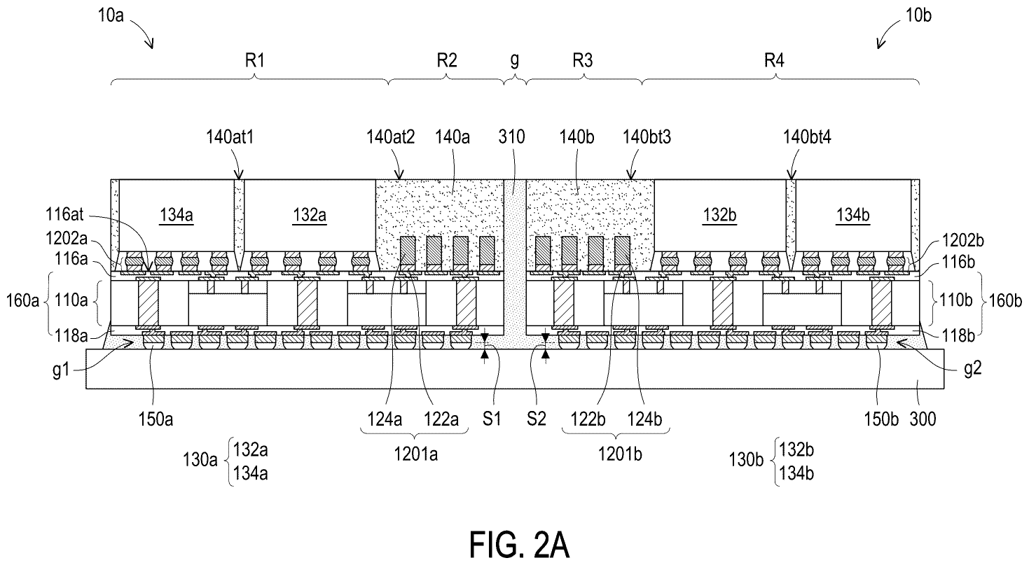

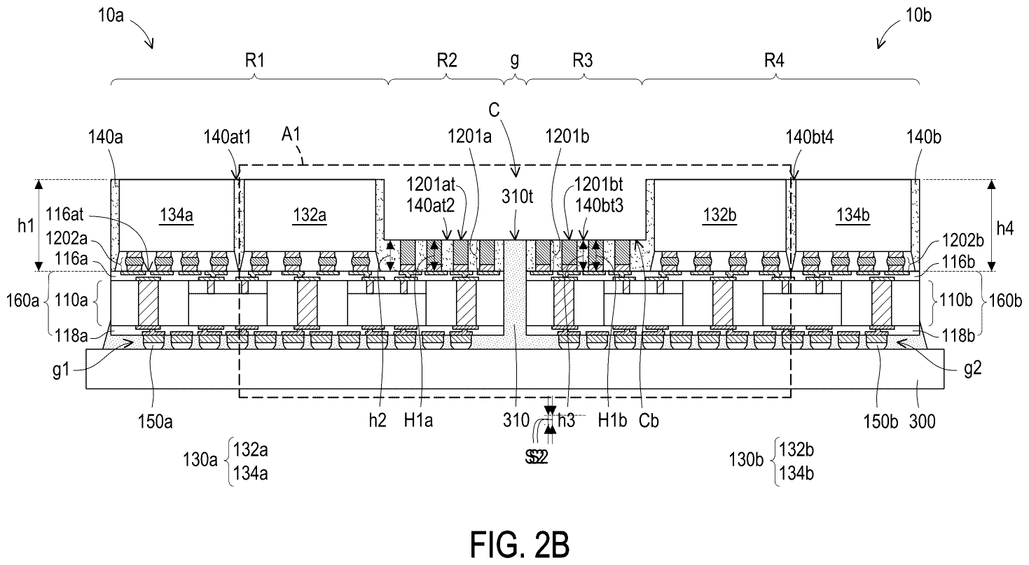

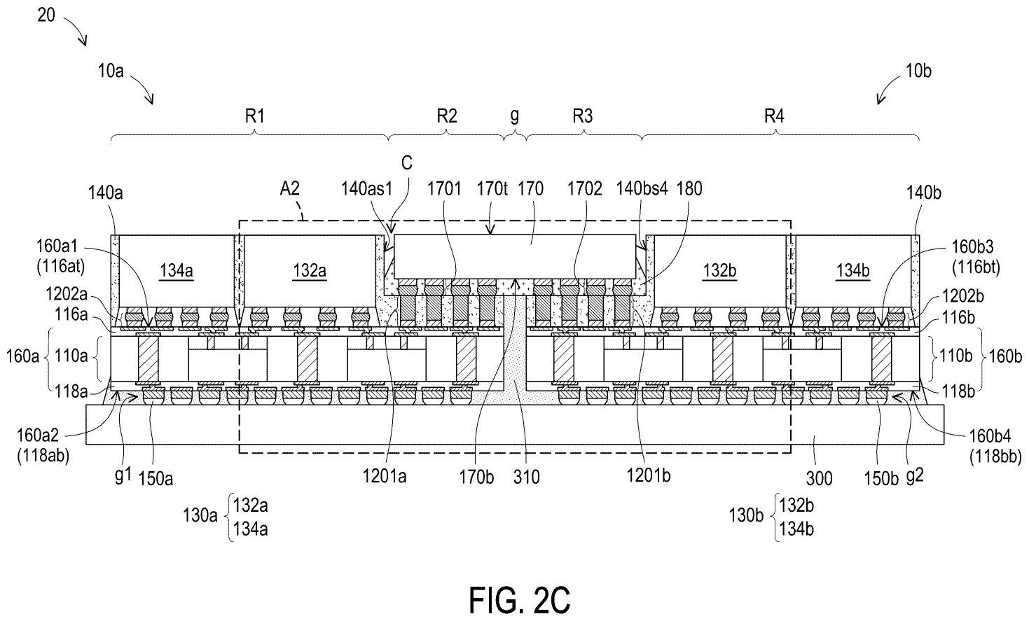

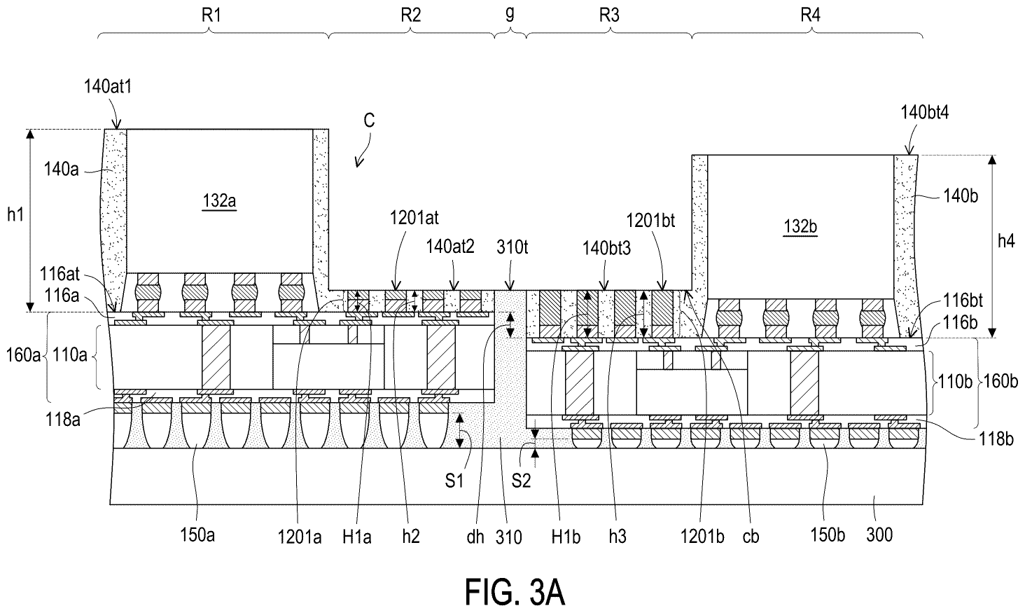

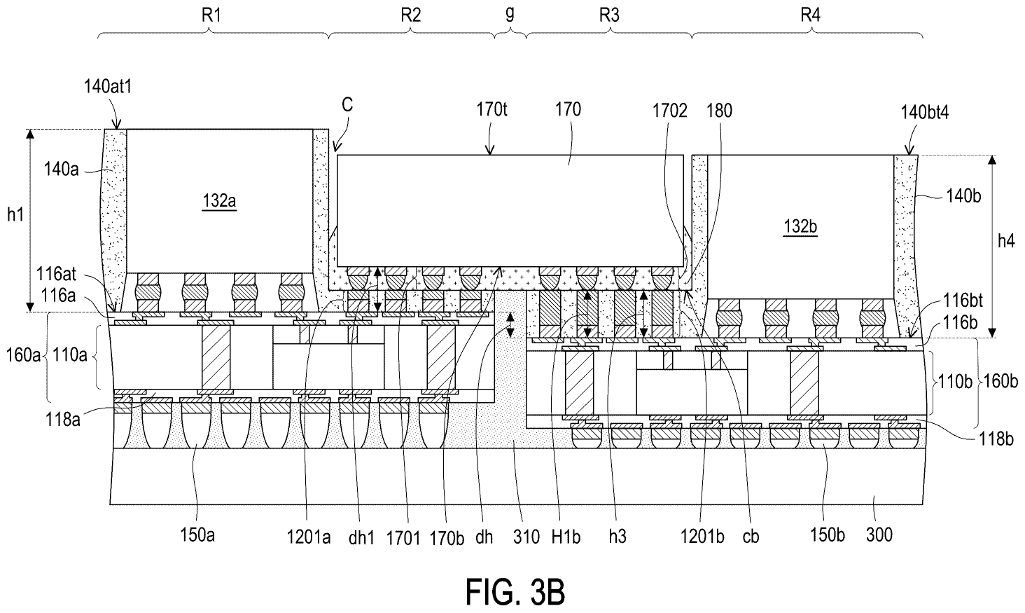

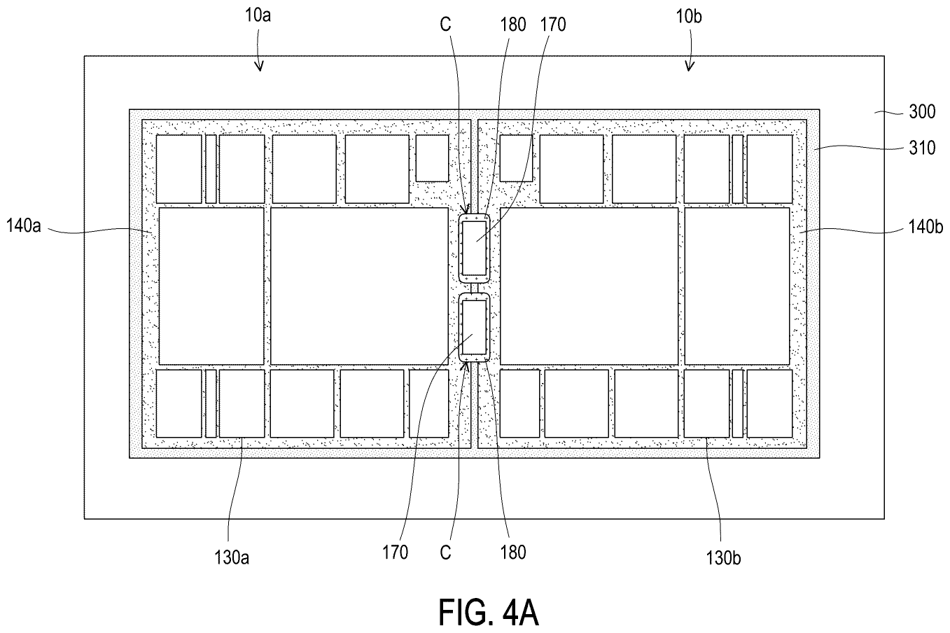

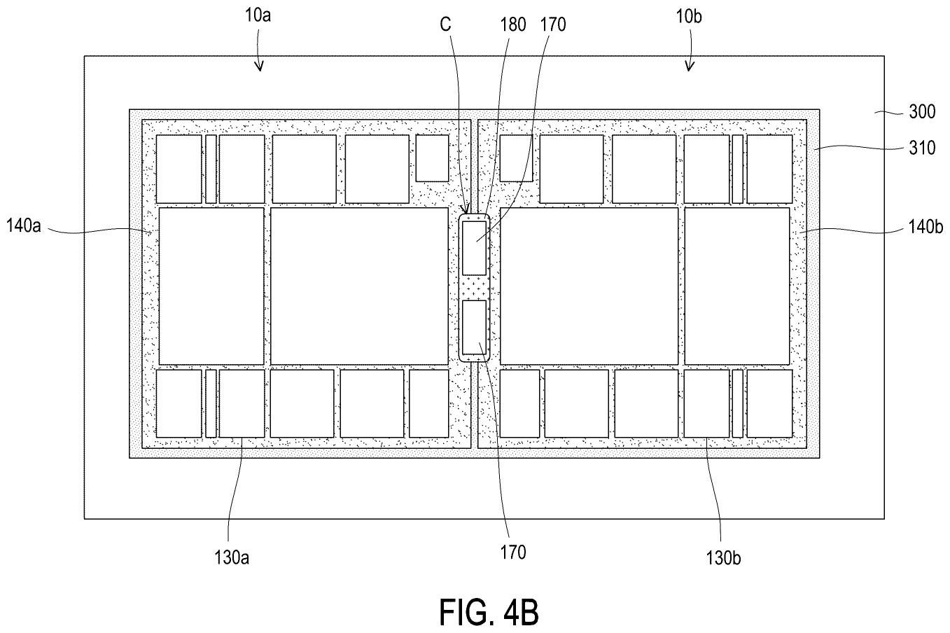

FIGS. 2A to 2C are schematic sectional views at various stages in a method of fabricating a semiconductor package 20 in accordance with some embodiments of the present disclosure. FIG. 3A is an enlargement view of area A1 in an alternative embodiment of FIG. 2B in accordance with some embodiments of the present disclosure. FIG. 3B is an enlargement view of area A2 in an alternative embodiment of FIG. 2C in accordance with some embodiments of the present disclosure. FIG. 4A is a top view of an embodiment of FIG. 2C in accordance with some embodiments of the present disclosure. FIG. 4B is a top view of an embodiment of FIG. 2C in accordance with some embodiments of the present disclosure. It should be noted herein that, in embodiment provided in FIGS. 2A to 2C, 3A to 3B and 4A to 4B, element numerals and partial content of the embodiments provided in FIGS. 1A to 1J are followed, the same or similar reference numerals being used to represent the same or similar elements, and description of the same technical content being omitted. For a description of an omitted part, reference may be made to the foregoing embodiment, and the descriptions thereof are omitted herein.

Referring to FIG. 2A, a first sub-package 10a and a second sub-package 10b are placed on a substrate 300 and are arranged side by side. In some embodiments, the first sub-package 10a has a first region R1 and a second region R2, and the second sub-package 10b has a third region R3 and a fourth region R4. The second region R2 and the third region R3 are adjacent to each other, so that the second region R2 and the third region R3 are located between the first region R1 and the fourth region R4. In some embodiments, the first region R1 of the sub-package 10a and the fourth region R4 of the second sub-package 10b may be similar to the device region DR of the sub-package 10 shown in FIG. 1J. The second region R2 of the sub-package 10a and the third region R3 of the second sub-package 10b may be similar to the bridge region DR of the sub-package 10 shown in FIG. 1J.

The first sub-package 10a and the second sub-package 10b may be similar to that of the sub-package 10 in FIG. 1J. In detail, the first sub-package 10a may include a first interposer 160a (similar to the interposer 160 of sub-package 10), a plurality of dies 130a (similar to the dies 130 of sub-package 10) disposed on the first interposer 160a in the first region R1 and a first insulating encapsulant 140a (which is similar to the insulating encapsulant 140 of sub-package 10) disposed on the first interposer 160a. The first interposer 160a may include a first interposer substrate 110a (similar to the interposer substrate 110 of the sub-package 10), a first redistribution structure 116a (similar to the redistribution structure 116 of the sub-package 10) disposed over the first interposer substrate 110a, first conductive connectors 1201a (similar to the first conductive connectors 1201 of the sub-package 10) disposed on the first redistribution structure 116a in the second region R2, third conductive connectors 1202a (similar to the second conductive connectors 1202 of the sub-package 10) disposed on the first redistribution structure 116a in the first region R1, a third redistribution structure 118a (similar to the redistribution structure 118 of the sub-package 10) disposed below the first interposer substrate 110a and first conductive terminals 150a (similar to the conductive terminals 150 of the sub-package 10) disposed between the third redistribution structure 118a and the substrate 300. The plurality of dies 130a, which includes a first die 132a and a third die 134a (similar to the dies 132 and 134 of the sub-package 10), are electrically connected to the first redistribution structure 116a through the third conductive connectors 1202a. The first conductive connectors 1201a each includes a conductive post 122a and a solder cap 124a in the first insulating encapsulant 140a.

The second sub-package 10b may include a second interposer 160b (similar to the interposer 160 of sub-package 10), a plurality of dies 130b (similar to the dies 130 of sub-package 10) disposed on the second interposer 160b in the fourth region R4 and a second insulating encapsulant 140b (similar to the insulating encapsulant 140 of sub-package 10) disposed on the second interposer 160b. The second interposer 160b may include a second interposer substrate 110b (similar to the interposer substrate 110 of the sub-package 10), a second redistribution structure 116b (similar to the redistribution structure 116 of the sub-package 10) disposed over the second interposer substrate 110b, second conductive connectors 1201b (similar to the first conductive connectors 1201 of the sub-package 10) disposed on the second redistribution structure 116b in the third region R3, fourth conductive connectors 1202b (similar to the second conductive connectors 1202 of the sub-package 10) disposed on the second redistribution structure 116b in the fourth region R4, a fourth redistribution structure 118b (similar to the redistribution structure 118 of the sub-package 10) disposed below the second interposer substrate 110b and second conductive terminals 150b (similar to the conductive terminals 150 of the sub-package 10) disposed between the fourth redistribution structure 118b and the substrate 300. The plurality of dies 130b, which includes a second die 132b and a fourth die 134b (similar to the dies 132 and 134 of the sub-package 10), are electrically connected to the second redistribution structure 116b through the fourth conductive connectors 1202b. The second conductive connectors 1201b each includes a conductive post 122b and a solder cap 124b in the second insulating encapsulant 140b.

In some embodiments, the fabrication of first sub-package 10a and the second sub-package 10b may be similar to that of the sub-package 10 in FIGS. 1A to 1J. The first sub-package 10a and the second sub-package 10b may be fabricated in the same or different fabrication processes. The embodiment is not limited.

In some embodiments, the substrate 300 may include or be made of a semiconductor material (such as silicon, germanium or the like) or an insulating core material (such as fiberglass resin, bismaleimide triazine (BT) resin or the like). The substrate 300 may include metallization layers (not shown) and vias (not shown) for electrical connection, so that the first sub-package 10a and the second sub-package 10b may be electrically connected to the substrate 300 by the first conductive terminals 150a and the second conductive terminals 150b.

In some embodiments, once the first conductive terminals 150a and the second conductive terminals 150b are in physical contact with the corresponding contact pads (not shown) of the substrate 300, a reflow process may be performed to bond the first conductive terminals 150a and the second conductive terminals 150b to the substrate 300.

In some embodiments as shown in FIG. 2A, a standoff S1 of the first conductive terminals 150a may be substantially the same with a standoff S2 of the second conductive terminals 150b, so that the top surface 116at of the first redistribution structure 116a may substantially level with the top surface 116bt of the second redistribution structure 116b and the top surfaces 140at1 and 140at2 of the first insulating encapsulant 140a in the first region R1 and the second region R2 may substantially level with the top surfaces 140bt3 and 140bt4 of the second insulating encapsulant 140b in the third region R3 and the fourth region R4. Here the standoff may refer to an average height of the conductive terminals after reflow process. In other embodiments, a standoff S1 of the first conductive terminals 150a may be different from a standoff S2 of the second conductive terminals 150b due to process variation during bonding the first sub-package 10a and the second sub-package 10b on the substrate 300. For example, the standoff S1 of the first conductive terminals 150a may be larger than the standoff S2 of the second conductive terminals 150b, so that the top surface 116at of the first redistribution structure 116a may be higher than the top surface 116bt of the second redistribution structure 116b, and the top surfaces 140at1 and 140at2 of the first insulating encapsulant 140a in the first region R1 and the second region R2 may also be higher than the top surfaces 140bt3 and 140bt4 of the second insulating encapsulant 140b in the third region R3 and the fourth region R4.

In some embodiments, a standoff difference (i.e. |S1-S2|) between the standoff S1 and the standoff S2 may be less than about 50 μm. In some embodiment, a level height difference dh (shown in FIG. 3A) between the top surface 116at of the first redistribution structure 116a and the top surface 116bt of the second redistribution structure 116b and/or a level height difference between the top surface 140att1 of the first insulating encapsulant 140a in the first region R1 and the top surface 140bt4 of the second insulating encapsulant 140b in the fourth region R4 may be similar to the standoff difference between the standoff S1 and the standoff S2.

Still referring to FIG. 2A, an insulating material 310 (also called a filling material or an underfill) is filled into a gap g between the first sub-package 10a and the second sub-package 10b. The insulating material 310 may include a material such as a molding compound, an epoxy, an underfill compound, a molding underfill (MUF), a resin, or the like. In some embodiments, the insulating material 310 further extends to a first gap g1 between the first interposer 160a and the substrate 300 and a second gap g2 between the second interposer 160b and the substrate 300, so that the first conductive terminals 150a and the second conductive terminals 150b may be surrounded by the insulating material 310.

Referring to FIGS. 2B and 3A, a cavity C is formed to expose the first conductive connectors 1201a of the first interposer 160a and the second conductive connectors 1201b of the second interposer 160b. The cavity C may be between the first die 132a and the second die 132b. For example, a portion of the first insulating encapsulant 140a in the second region R2, a portion of the second insulating encapsulant 140b in the third region R3 and a portion of the insulating material 310 between the first sub-package 10a and the second sub-package 10b are removed by, for example, routing, sawing, or other suitable method, until the first conductive connectors 1201a and the second conductive connectors 1201b are exposed. In some embodiments, from the top view (referring to FIG. 4A or FIG. 4B), the cavity C may have a rectangular shape with round corners, and the round corners may be caused by the rotating blade during routing. However, the shape of the cavity C is not limited. The shape of the cavity C from the top view may be circular, rectangular, polygon or other suitable shape. Please note that the number and arrangement of the cavity C is not limited to the drawings of the embodiments, and may be selected and designated based on the demand and design requirements.

In some embodiments, a portion of the first conductive connectors 1201a or a portion of the second conductive connectors 1201b is removed during forming the cavity C. In some embodiments, a bottom surface Cb of the cavity C substantially levels with a top surface 310t of the insulating material 310, a top surface 1201at of the first conductive connectors 1201a and a top surface 1201bt of the second conductive connectors 1201b. The bottom surface Cb of the cavity C may be composed of a top surface 140at2 of the first insulating encapsulant 140a in the second region R2, a top surface 140bt3 of the second insulating encapsulant 140b in the third region R3, a top surface 310t of the insulating material 310, a top surface 1201at of the first conductive connectors 1201a and a top surface 1201bt of the second conductive connectors 1201b.

In the embodiment shown in FIG. 2B, the first conductive connectors 1201a and the second conductive connectors 1201b may have substantially the same height after the forming of the cavity C since the standoff S1 and the standoff S2 are substantially the same. However, in an alternative embodiment where the standoff S1 of the first conductive terminals 150a is different from the standoff S2 of the second conductive terminals 150b, the first conductive connectors 1201a and the second conductive connectors 1201b may have different heights after the forming of the cavity C. For example, as shown in FIG. 3A, when the standoff S1 of the first terminals 150a is larger than the standoff S2 of the second terminals 150b, and a height H1a of the first conductive connectors 1201a is smaller than a height H1b of the second conductive connectors 1201b. In such embodiment, the difference between the height H1b of the second conductive connectors 1201b and the height H1a of the first conductive connectors 1201a may substantially equal to the level height difference dh. However, the disclosure is not limited thereto, in other embodiments, when a standoff S1 of the first terminals 150a is smaller than a standoff S2 of the second terminals 150b, a height H1a of the first conductive connectors 1201a may be greater than a height H1b of the second conductive connectors 1201b.

In some embodiments, after the forming of the cavity C, a thickness h1 of the first insulating encapsulant 140a in the first region R1 is greater than a thickness h2 of the first insulating encapsulant 140a in the second region R2, and a thickness h4 of the second insulating encapsulant 140b in the fourth region R4 is greater than a thickness h3 of the second insulating encapsulant 140b in the third region R3.

In some embodiments, a thickness h2 of the first insulating encapsulant 140a in the second region R2 is substantially the same to the height H1a of the first conductive connectors 1201a, and a thickness h3 of the second insulating encapsulant 140b in the third region R3 is substantially the same to the height H1b of the second conductive connectors 1201b.

Referring to FIGS. 2C and 3B, a bridge die 170 is disposed in the cavity C to electrically connect with the first interposer 160a and the second interposer 160b by the first conductive connectors 1201a and the second conductive connectors 1201b. A dimension (such as a width or a length) of the bridge die 170 may be smaller than that of the cavity C. Please note that the number and arrangement of the bridge die 170 is not limited to the drawings of the embodiments, and may be selected and designated based on the demand and design requirements.

The bridge die 170 includes a plurality of conductive connectors (including first conductive connectors 1701 and second conductive connectors 1702) for external connection. The first conductive connectors 1701 of the bridge die 170 are physically and electrically connected to the first conductive connectors 1201a of the first interposer 160a, and the second conductive connectors 1702 of the bridge die 170 are physically and electrically connected to the second conductive connectors 1201b of the second interposer 160b.

In some embodiments, the first conductive connectors 1701 and the second conductive connectors 1702 each include a conductive pillar and a solder cap, but this is not limited thereto. In other embodiments, the first conductive connectors 1701 and the second conductive connectors 1702 may each include a conductive pillar and are free of solder cap.

In some embodiments, a top surface 170t of the bridge die 170 may be higher than, lower than or level with a top surface 140at1 of the first insulating encapsulant 140a in the first region R1 or a top surface 140bt4 of the second insulating encapsulant 140b in the fourth region R4, which is not limited.

Referring to FIGS. 2C and 3B, an underfill 180 is formed in the cavity C. The underfill 180 may be located in a gap between a bottom surface 170b of the bridge die 170 and a top surface 140at2 (labeled in FIGS. 2B and 3A) of the first insulating encapsulant 140a in the second region R2 and between a bottom surface 170b of the bridge die 170 and a top surface 140bt3 (labeled in FIGS. 2B and 3A) of the second insulating encapsulant 140b in the third region R3 to laterally encapsulate the first conductive connectors 1701 and the second conductive connectors 1702. The underfill 180 may further extend to a gap between an inner sidewall 140as1 of the first insulating encapsulant 140a in the first region R1 and a sidewall of the bridge die 170 and/or between an inner sidewall 140bs4 of the second insulating encapsulant 140b in the fourth region R4 and a sidewall of the bridge die 170. In some embodiments, the underfill 180 may be formed by an underfill dispensing process, a capillary flow process, or any other suitable method. The underfill 180 may be a material such as a molding compound, an epoxy, an underfill compound, a molding underfill (MUF), a resin, or the like.

Based on the above, the fabrication of a semiconductor package 20 and/or the semiconductor package 20A is substantially completed.

Referring to FIG. 2C, the semiconductor package 20 includes a substrate 300, a first sub-package 10a, a second sub-package 10b and a bridge die 170. The first sub-package 10a and the second sub-package 10b are arranged side by side on the substrate 300. The first sub-package 10a includes a first interposer 160a, a plurality of dies 130a (including a first die 132a and a third die 134a), a first insulating encapsulant 140a and a first conductive terminals 150a. The first interposer 160a has a first surface 160a1 and a second surface 160a2 opposite to the first surface 160a1. The first die 132a and the third die 134a are disposed on the first surface 160a1 of the first interposer 160a. The first insulating encapsulant 140a is disposed on the first surface 160a1 of the first interposer 160a and encapsulates the first die 132a and the third die 134a. The first conductive terminals 150a are disposed between the second surface 160a2 of the first interposer 160a and the substrate 300. In other hands, the second sub-package 10b includes a second interposer 160b, a plurality of dies 130b (including a second die 132b and a fourth die 134b), a second insulating encapsulant 140b and a second conductive terminals 150b. The second interposer 160b has a third surface 160b3 and a fourth surface 160b4 opposite to the third surface 160b3. The second die 132b and the fourth die 134b are disposed on the third surface 160b3 of the second interposer 160b. The second insulating encapsulant 140b is disposed on the third surface 160b3 of the second interposer 160b and encapsulates the second die 132b and the fourth die 134b. The second conductive terminals 150b are disposed between the fourth surface 160b4 of the second interposer 160b and the substrate 300. The bridge die 170 is disposed over the first insulating encapsulant 140a and the second insulating encapsulant 140b. The bridge die 170 is electrically connected between the first interposer 160a and the second interposer 160b. In some embodiments, the first die 132a and the second die 132b are electrically connected to each other through the first interposer 160a, the second interposer 160b and the bridge die 170.

In some embodiments, the first sub-package 10a has a first region R1 and a second region R2, and the second sub-package 10b has a third region R3 and a fourth region R4. The first die 132a and the third die 134a are located in the first region R1, and the second die 132b and the fourth die 134b are located in the fourth region R4. The bridge die 170 is located in the second region R2 and the third region R3 and between the first die 132a and the second die 132b. The bridge die 170 may overlap a gap g between the first sub-package 10a and the second sub-package 10b and the gap may be filled with an insulating material 310. In some embodiments, the bridge die 170 is not overlapped with the first die 132a and the second die 132b in a direction vertical to a surface of the substrate 300 on which the first sub-package 10a and the second sub-package 10b are mounted.

In some embodiments, the first interposer 160a includes a first interposer substrate 110a, a first redistribution structure 116a disposed over the first interposer substrate 110a, first conductive connectors 1201a disposed on the top surface 116at of the first redistribution structure 116a in the second region R2, third conductive connectors 1202a disposed on the top surface 116at of the first redistribution structure 116a in the first region R1, and a third redistribution structure 118a disposed below the first interposer substrate 110a. In some embodiments, the first surface 160a1 of the first interposer 160a may refer to the top surface 116at of the first redistribution structure 116a, and the second surface 160a2 of the first interposer 160a may refer to the bottom surface 118ab of the third redistribution structure 118a.

In some embodiments, the second interposer 160b includes a second interposer substrate 110b, a second redistribution structure 116b disposed over the second interposer substrate 110b, second conductive connectors 1201b disposed on the top surface 116bt of the second redistribution structure 116b in the third region R3, fourth conductive connectors 1202b disposed on the top surface 116bt of the second redistribution structure 116b in the fourth region R4, a fourth redistribution structure 118b disposed below the second interposer substrate 110b and second conductive terminals 150b disposed between the fourth redistribution structure 118b and the substrate 300. In some embodiments, the third surface 160b3 of the second interposer 160b may refer to the top surface 116bt of the second redistribution structure 116b, and the fourth surface 160b4 of the second interposer 160b may refer to the bottom surface 118bb of the fourth redistribution structure 118b.

In some embodiments, the first die 132a and the third die 134a are electrically connected to the first redistribution structure 116a through the third conductive connectors 1202a. The second die 132b and the fourth die 134b are electrically connected to the second redistribution structure 116b through the fourth conductive connectors 1202b. The bridge die 170 is electrically connected to the first redistribution structure 116a through the first conductive connectors 1201a and is electrically connected to the second redistribution structure 116b through the second conductive connectors 1201b. In some embodiments, the first die 132a and the second die 132b are electrically connected to each other through the first redistribution structure 116a, the second redistribution structure 116b and the bridge die 170.

In some embodiments, the first insulating encapsulant 140a has a first thickness h1 (labeled in FIG. 2B) in the first region R1 and a second thickness h2 (labeled in FIG. 2B) in the second region R2, and the first thickness h1 is greater than the second thickness h2. The second insulating encapsulant 140b has a third thickness h3 (labeled in FIG. 2B) in the third region R3 and a fourth thickness h4 (labeled in FIG. 2B) in the fourth region R4, and the fourth thickness h4 is greater than the third thickness h3. In some embodiments, the second thickness h2 is substantially the same with the third thickness h3.

In some embodiments, a standoff S1 (labeled in FIG. 2A) of the first terminals 150a is substantially the same with a standoff S2 (labeled in FIG. 2A) of the second terminals 150b. In some embodiment, a top surface 140at2 (labeled in FIG. 2B) of the first insulating encapsulant 140a in the second region R2 substantially levels with a top surface 140bt3 (labeled in FIG. 2B) of the second insulating encapsulant 140b in the third region R3, and a top surface 140at1 (labeled in FIG. 2B) of the first insulating encapsulant 140a in the first region R1 substantially levels with a top surface 140bt4 (labeled in FIG. 2B) of the second insulating encapsulant 140b in the fourth region R4.

In some embodiments, the semiconductor package 20 may include multiple bridge dies 170 connecting between the first interposer 160a and the second interposer 160b. For example, in FIG. 4A, each bridge die 170 is located in respective cavity C, and thus a portion of the insulating material 310 may be located between the adjacent bridge dies 170. In another embodiment, as shown in FIG. 4B, multiple bridge dies 170 are located in a single cavity C, and the underfill 180 may be filled within a gap between the adjacent bridge dies 170.

Referring to FIG. 3B, the semiconductor package 20A is similar to the semiconductor package 20 in FIG. 2C, and the difference between the semiconductor package 20A and the semiconductor package 20 is that the semiconductor package 20A has a level height difference dh between the top surface 116at of the first redistribution structure 116a and the top surface 116bt of the second redistribution structure 116b caused by the standoff difference between the first conductive terminals 150a of the first sub-package 10a and the second conductive terminals 150b of the second sub-package 10b while mounting the first sub-package 10a and the second sub-package 10b on the substrate 300. Specifically, in FIG. 3B, the standoff S1 of the first terminals 150a is larger than the standoff S2 of the second terminals 150b, so that the top surface 116at of the first redistribution structure 116a is higher than the top surface 116bt of the second redistribution structure 116b. However, the disclosure is not limited thereto. In other embodiments, the standoff S1 of the first terminals 150a may be smaller than the standoff S2 of the second terminals 150b, so that the top surface 116at of the first redistribution structure 116a may be lower than the top surface 116bt of the second redistribution structure 116b.

In some embodiments, a top surface 140at2 (labeled in FIG. 3A) of the first insulating encapsulant 140a in the second region R2 substantially levels with a top surface 140bt3 (labeled in FIG. 3A) of the second insulating encapsulant 140b in the third region R3, and a top surface 140at1 (labeled in FIG. 3A) of the first insulating encapsulant 140a in the first region R1 does not level with a top surface 140bt4 (labeled in FIG. 3A) of the second insulating encapsulant 140b in the fourth region R4. In such embodiment, a level height difference between the top surface 140att1 of the first insulating encapsulant 140a in the first region R1 and the top surface 140bt1 of the second insulating encapsulant 140b in the fourth region R4 may be similar to the level height difference dh between the top surface 116at of the first redistribution structure 116a and the top surface 116bt of the second redistribution structure 116b.

In some embodiments, a third thickness h3 of the second insulating encapsulant 140b in the third region R3 is greater than a second thickness h2 of the first insulating encapsulant 140a in the second region R2. However, it is not limited and may depend on the standoffs of the first terminal 150a and the second terminal 150b. Therefore, in other embodiments, a third thickness h3 of the second insulating encapsulant 140b in the third region R3 may be smaller than a second thickness h2 of the first insulating encapsulant 140a in the second region R2.

In some embodiments, a first level height difference dh1 between a bottom surface 170b of the bridge die 170 and a top surface 116at of the first redistribution structure 116a is different from a second level height difference dh2 between the bottom surface 170b of the bridge die 170 and a top surface 116bt of the second redistribution structure 116b. For example, in FIG. 3B, the level height difference dh1 is smaller than the second level height difference dh2. However, it is not limited and may depend on the standoffs of the first terminal 150a and the second terminal 150b. Therefore, in other embodiments, a first level height difference dh1 may be greater than a second level height difference dh2.

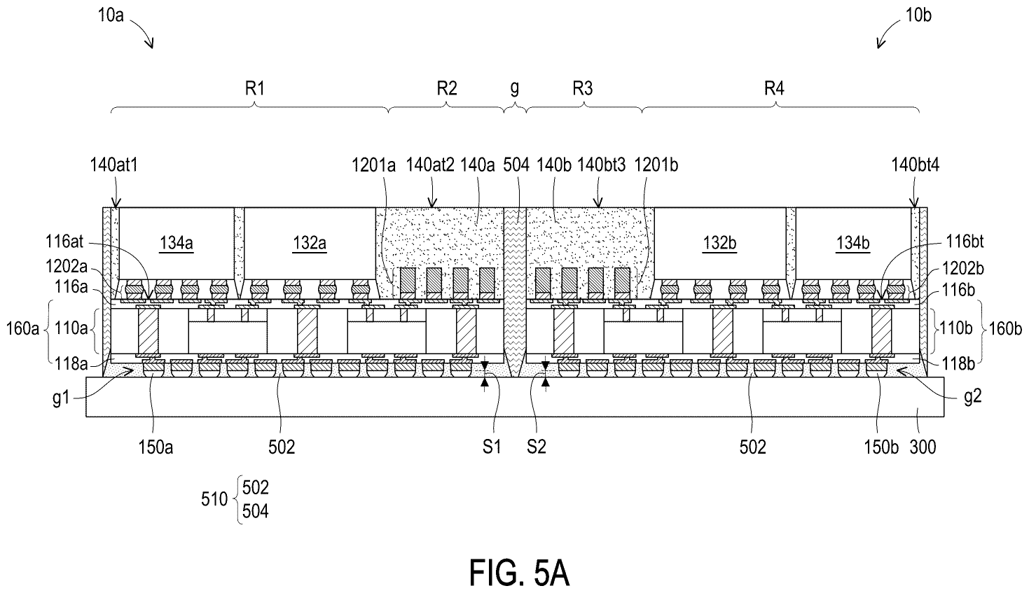

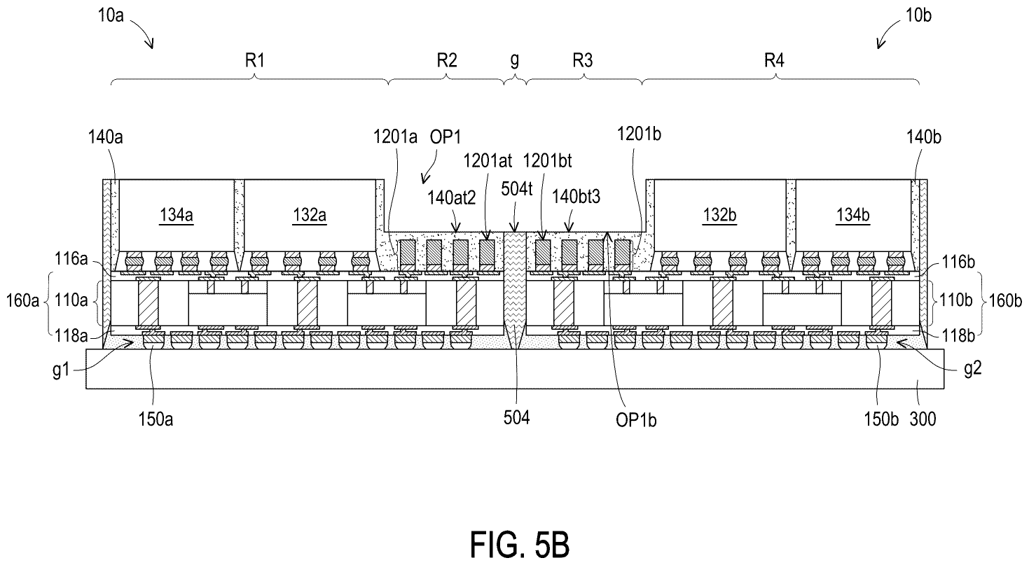

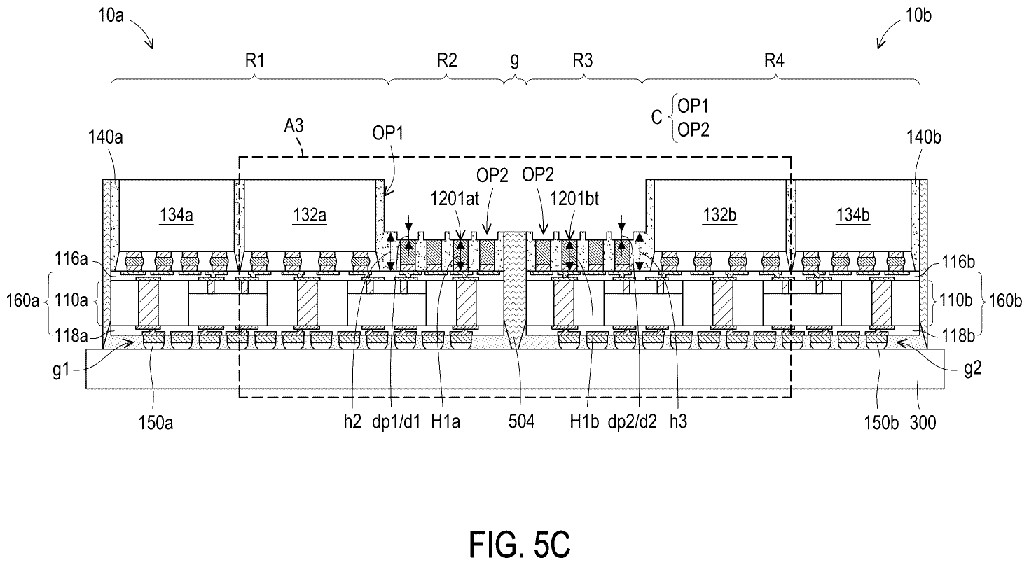

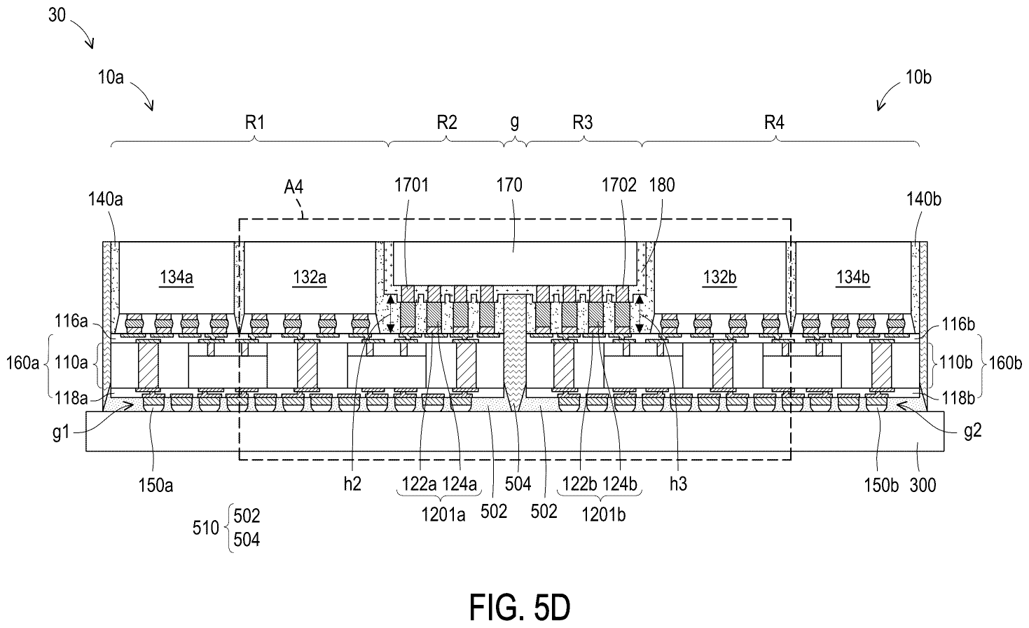

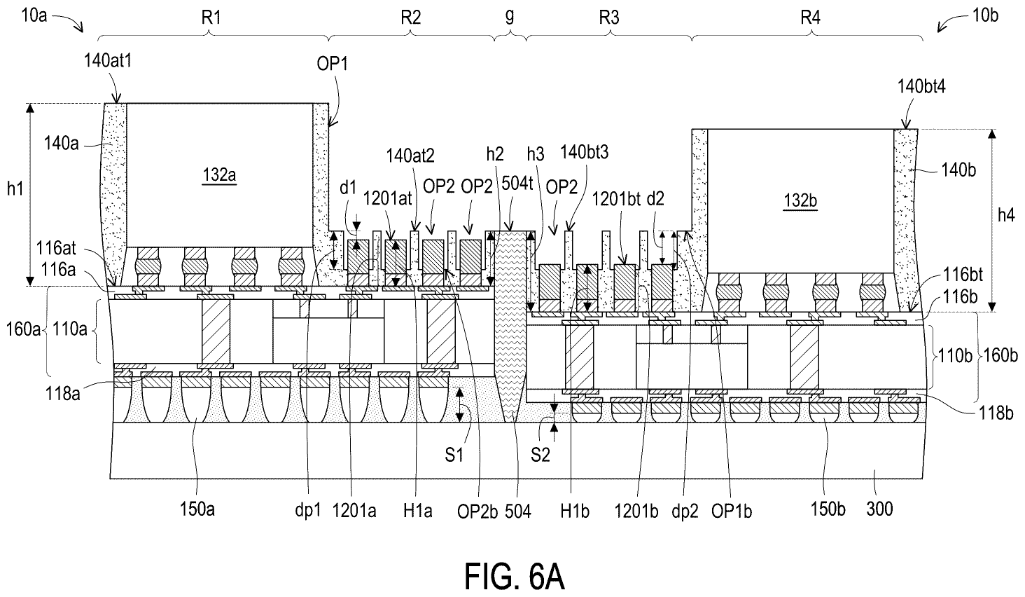

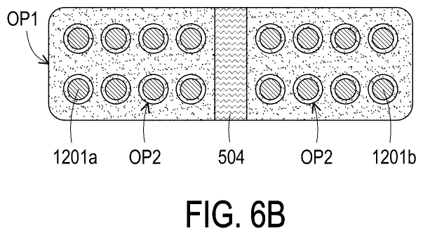

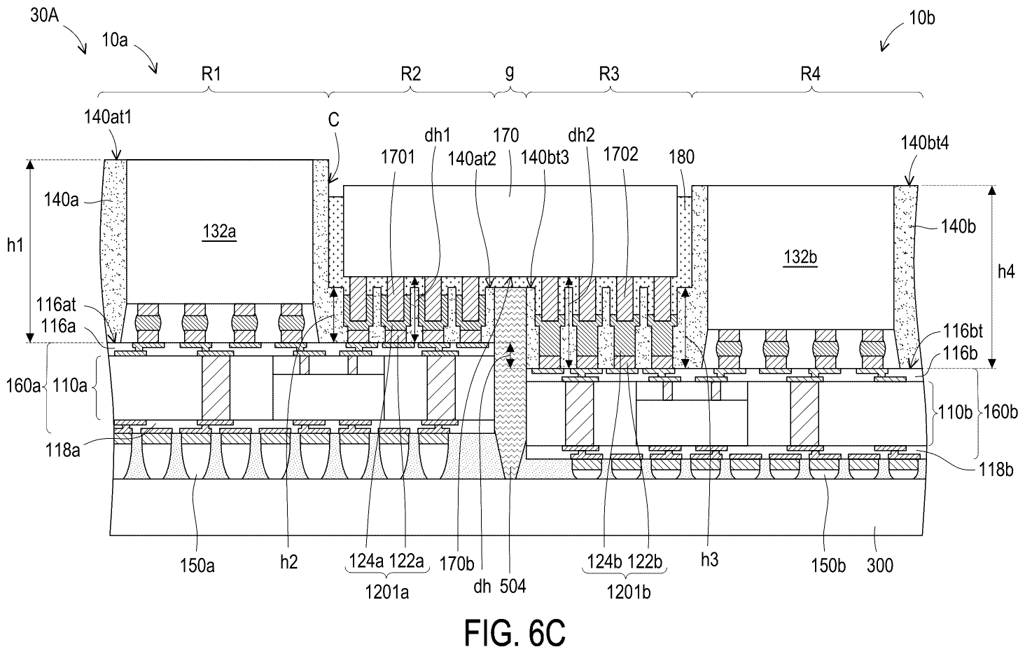

FIGS. 5A to 5D are schematic sectional views at various stages in a method of fabricating a semiconductor package 30 in accordance with some embodiments of the present disclosure. FIG. 6A is an enlargement view of an area A3 in an alternative embodiment of FIG. 5C in accordance with some embodiments of the present disclosure. FIG. 6B is a top view of an embodiment of cavity C in FIG. 5C or FIG. 6A in accordance with some embodiments of the present disclosure. FIG. 6C is an enlargement view of an area A4 in an alternative embodiment of FIG. 5D in accordance with some embodiments of the present disclosure. It should be noted herein that, in embodiment provided in FIGS. 5A to 5D and 6A to 6C, element numerals and partial content of the embodiments provided in FIGS. 2A to 2C and 3A to 3B are followed, the same or similar reference numerals being used to represent the same or similar elements, and description of the same technical content being omitted. For a description of an omitted part, reference may be made to the foregoing embodiment, and the descriptions thereof are omitted herein.

Referring to FIG. 5A, the first sub-package 10a and the second sub-package 10b are bonded to the substrate 300 and arranged side by side, which is similar to the mounting process of the first sub-package 10a and the second sub-package 10b described in FIG. 2A. Then an underfill 502 is formed in a first gap g1 between the first interposer 160a and the substrate 300 and a second gap g2 between the second interposer 160b and the substrate 300, so that the first conductive terminals 150a and the second conductive terminals 150b may be surrounded by the underfill 502. Further, a filling material 504 is formed to laterally encapsulate the first sub-package 10a and the second sub-package 10b. The filling material 504 may fill a gap g between the first sub-package 10a and the second sub-package 10b. In some embodiments, the filling material may cover side surfaces of the first sub-package 10a and the second sub-package 10b. The filling material 504 and the underfill 502 may be collectively referred to an insulating material 510. The filling material 504 and the underfill 502 may each include a material such as a molding compound, an epoxy, an underfill compound, a molding underfill (MUF), a resin, or the like. The filling material 504 and the underfill 502 may be formed by the same or different material. In an embodiment where the filling material 504 and the underfill 502 are formed by the same material, the insulating material 510 may be similar to the insulating material 310 described in FIG. 2A.

In some embodiments as shown in FIG. 5A, a standoff S1 of the first conductive terminals 150a may be substantially the same with a standoff S2 of the second conductive terminals 150b, so that the top surface 116at of the first redistribution structure 116a may substantially level with the top surface 116bt of the second redistribution structure 116b and the top surfaces 140at1 and 140at2 of the first insulating encapsulant 140a in the first region R1 and the second region R2 may substantially level with the top surfaces 140bt3 and 140bt4 of the second insulating encapsulant 140b in the third region R3 and the fourth region R4.

In other embodiments, a standoff S1 of the first conductive terminals 150a may be different from a standoff S2 of the second conductive terminals 150b due to process variation during bonding the first sub-package 10a and the second sub-package 10b on the substrate 300. For example, the standoff S1 of the first conductive terminals 150a may be larger than the standoff S2 of the second conductive terminals 150b, so that the top surface 116at of the first redistribution structure 116a may be higher than the top surface 116bt of the second redistribution structure 116b, and the top surfaces 140at1 and 140at2 of the first insulating encapsulant 140a in the first region R1 and the second region R2 may also be higher than the top surfaces 140bt3 and 140bt4 of the second insulating encapsulant 140b in the third region R3 and the fourth region R4.

In some embodiments, a standoff difference (i.e. |S1-S2|) between the standoff S1 and the standoff S2 may be less than about 50 μm. In some embodiment, a level height difference dh (shown in FIG. 6A) between the top surface 116at of the first redistribution structure 116a and the top surface 116bt of the second redistribution structure 116b and/or a level height difference between the top surface 140at1 of the first insulating encapsulant 140a in the first region R1 and the top surface 140bt4 of the second insulating encapsulant 140b in the fourth region R4 may be similar to the standoff difference between the standoff S1 and the standoff S2.

Referring to FIGS. 5B and 5C and FIG. 6A, a cavity C is formed between the first die 132a and the second die 132b to expose the first conductive connectors 1201a of the first interposer 160a and the second conductive connectors 1201b of the second interposer 160b. The cavity C is formed by the first opening OP1 and the second openings OP2 as described in the following steps. In FIG. 5B, a portion of the first insulating encapsulant 140a in the second region R2, a portion of the second insulating encapsulant 140b in the third region R3 and a portion of the filling material 504 between the first sub-package 10a and the second sub-package 10b are removed by, for example, routing, sawing, or other suitable method to form a first opening OP1. The first opening OP1 does not expose the first conductive connectors 1201a of the first interposer 160a and the second conductive connectors 1201b of the second interposer 160b. In other words, a bottom surface OP1b of the first opening OP1 is higher than top surfaces 1201at of the first conductive connectors 1201a and top surfaces 1201bt of the second conductive connectors 1201b. The bottom surface OP1b of the first opening OP1 may be composed of a top surface 140at2 of the first insulating encapsulant 140a in the second region R2, a top surface 140bt3 of the second insulating encapsulant 140b in the third region R3 and a top surface 504t of the filling material 504. In some embodiments, the top surface 140at2 of the first insulating encapsulant 140a in the second region R2, the top surface 140bt3 of the second insulating encapsulant 140b in the third region R3 and the top surface 504t of the filling material 504 are coplanar.

In some embodiments, from the top view (as shown in FIG. 6B), the first opening OP1 may have a rectangular shape with round corners, and the round corners may be caused by the rotating blade during routing. However, the shape of the first opening OP1 is not limited. The shape of the first opening OP1 from the top view may be circular, rectangular, polygon or other suitable shape.

Then, in FIG. 5C, a plurality of second openings OP2 are formed in the first insulating encapsulant 140a and the second insulating encapsulant 140b exposed by the first opening OP1. The second openings OP2 expose the corresponding first conductive connectors 1201a and the corresponding second conductive connectors 1201b respectively. The second opening OP2 may be formed by laser drilling or other suitable method to remove the first insulating encapsulant 140a or the second insulating encapsulant 140b until the top surface 1201at of the first conductive connector 1201a or the top surface 1201bt of the second conductive connector 1201b is exposed.

In some embodiments, from the top view as shown in FIG. 6B, the second openings OP2 may each have circular shape. However, the shapes of the second openings OP2 are not limited. The shapes of the second openings OP2 from the top view may be circular, rectangular, polygon or other suitable shape. The second openings OP2 are spaced apart from each other by the first insulating encapsulant 140a or the second insulating encapsulant 140b.

In some embodiments, a first depth dp1 of the second opening OP2 in the second region R2 may be greater than or equal to a first distance d1 between a top surface 1201a of the first conductive connector 1201a and a bottom surface OP1b of the first opening OP1, and a second depth dp2 of the second opening OP2 in the third region R3 may be greater than or equal to a second distance d2 between a top surface 1201bt of the second conductive connector 1201b and a bottom surface OP1b of the first opening OP1.

In some embodiments, a diameter or a width of the second opening OP2 may be larger than, equal to or smaller than a diameter or a width of the corresponding first conductive connector 1201a and the corresponding second conductive connector 1201b, which is not limited.

In an embodiment where the diameter of the second opening OP2 is larger than that of the corresponding first conductive connector 1201a or the corresponding second conductive connector 1201b, a portion of a sidewall of the first conductive connector 1201a or a portion of a sidewall of the second conductive connector 1201b may be exposed by the second opening OP2 as shown in FIG. 6A. In other words, a bottom surface OP2b of the second opening OP2 may be lower than the top surface 1201at of the first conductive connector 1201a or the top surface 1201bt of the second conductive connector 1201b. However, it is not limited, in other embodiments, a bottom surface OP2b of the second opening OP2 may substantially level with the top surface 1201at of the first conductive connector 1201a or the top surface 1201bt of the second conductive connector 1201b.

In some embodiments, a height H1a of the first conductive connector 1201a and a height H1b of the second conductive connector 1201b are substantially the same, a thickness h2 of the first insulating encapsulant 140a in the second region R2 is larger than the height H1a of the first conductive connector 1201a, and a thickness h3 of the second insulating encapsulant 140b in the third region R3 is larger than the height H1b of the second conductive connector 1201b.

In an embodiments where the standoff S1 of the first conductive terminals 150a is larger than the standoff S2 of the second conductive terminals 150b, the first distance d1 is smaller than the second distance d2, as shown in FIG. 6B. However, the disclosure is not limited. In other embodiments, the first distance d1 may be smaller than or substantially equal to the second distance d2 depending on the standoff difference between the first terminals 150a and the second terminals 150b.

Referring to FIGS. 5D and 6C, a bridge die 170 is disposed in the cavity C to electrically connect with the first interposer 160a and the second interposer 160b by the first conductive connectors 1201a and the second conductive connectors 1201b. A dimension (such as a width or a length) of the bridge die 170 may be smaller than that of the cavity C.

The bridge die 170 includes a plurality of conductive connectors (including first conductive connectors 1701 and second conductive connectors 1702) for external connection. The first conductive connectors 1701 of the bridge die 170 are bonded to the first conductive connectors 1201a of the first interposer 160a in the second openings OP2 in the second region R2. The second conductive connectors 1702 of the bridge die 170 are bonded to the second conductive connectors 1201b of the second interposer 160b in the second openings OP2 in the third region R3. In some embodiments, a diameter or a width of the first conductive connectors 1701 and the second conductive connectors 1702 of the bridge die 170 is smaller than that of the second openings OP2, so that the first conductive connectors 1701 and the second conductive connectors 1702 of the bridge die 170 may be disposed in the corresponding second openings OP2 (labeled in FIGS. 5C and 6A).

In some embodiments, the first conductive connectors 1701 and the second conductive connectors 1702 of the bridge die 170 may be conductive pillars, but it is not limited. In other embodiments, the first conductive connectors 1701 and second conductive connectors 1702 of the bridge die 170 may each include a conductive pillar and a solder cap.

In some embodiments, the first conductive connectors 1701 of the bridge die 170 may be embedded in the solder caps 124a of the first conductive connectors 1201a, and the second conductive connectors 1702 of the bridge die 170 may be embedded in the solder caps 124b of the second conductive connectors 1201b. The solder caps 122a or 122b may absorb or balance the level height difference (such as level height difference dh) or the standoff difference between the first terminals 150a and the second terminals 150b.

Referring to FIGS. 5D and 6C, an underfill 180 is formed in the cavity C. The underfill 180 may be located in a gap between an inner sidewall of the first insulating encapsulant 140a in the first region R1 and a sidewall of the bridge die 170 and between an inner sidewall of the second insulating encapsulant 140b in the fourth region R4 and a sidewall of the bridge die 170. In some embodiments, the underfill 180 may further extend to the second openings OP2 to laterally encapsulate the first conductive connectors 1701 and the second conductive connectors 1702. In some embodiments, the underfill 180 may also be located between the bottom surface 170b of the bridge die 170 and the filling material 504.

Based on the above, the fabrication of a semiconductor package 30 or a semiconductor package 30A is substantially completed.

Referring to FIG. 5D, the semiconductor package 30 is similar to the semiconductor package 20 in FIG. 2C, and the difference between the semiconductor package 30 and the semiconductor package 20 is that the first conductive connectors 1701 of the bridge die 170 in the semiconductor package 30 are partially disposed in the first insulating encapsulant 140a, and the second conductive connectors 1702 of the bridge die 170 are partially disposed in the second insulating encapsulant 140b. The underfill 180 may be located between the first conductive connectors 1701 of the bridge die 170 and the first insulating encapsulant 140a and/or between the second conductive connectors 1702 of the bridge die 170 and the second insulating encapsulant 140b.

In some embodiments, the semiconductor package 30 includes an insulating material 510. The insulating material 510 may include an underfill 502 and a filling material 504. The underfill 502 may be disposed between the first interposer 160a and the substrate 300 as well as between the second interposer 160b and the substrate 300. The filling material 504 may be disposed between the first interposer 160a and the second interposer 160b as well as between the first insulating encapsulant 140a and the second insulating encapsulant 140b. In some embodiments, the filling material 504 is disposed between the first conductive connectors 1701 of the bridge die 170 and the second conductive connectors 1702 of the bridge die 170.

Referring to FIG. 6C, the semiconductor package 30A is similar to the semiconductor package 30, and the difference between the semiconductor package 30A and the semiconductor package 30 is that the semiconductor package 30A has a level height difference dh between the top surface 116at of the first redistribution structure 116a and the top surface 116bt of the second redistribution structure 116b caused by the standoff difference between the first conductive terminals 150a of the first sub-package 10a and the second conductive terminals 150b of the second sub-package 10b while mounting the first sub-package 10a and the second sub-package 10b on the substrate 300. Specifically, in FIG. 6C, the standoff S1 of the first terminals 150a is larger than the standoff S2 of the second terminals 150b, so that the top surface 116at of the first redistribution structure 116a is higher than the top surface 116bt of the second redistribution structure 116b. However, the embodiment is not limited thereto. In other embodiments, the standoff S1 of the first terminals 150a may be smaller than the standoff S2 of the second terminals 150b, so that the top surface 116at of the first redistribution structure 116a may be lower than the top surface 116bt of the second redistribution structure 116b.

In some embodiments, a top surface 140at2 of the first insulating encapsulant 140a in the second region R2 substantially levels with a top surface 140bt3 of the second insulating encapsulant 140b in the third region R3, and a top surface 140at1 of the first insulating encapsulant 140a in the first region R1 does not level with a top surface 140bt1 of the second insulating encapsulant 140b in the fourth region R4. In such embodiment, a level height difference between the top surface 140at1 of the first insulating encapsulant 140a in the first region R1 and the top surface 140bt1 of the second insulating encapsulant 140b in the fourth region R4 may be similar to the level height difference dh.

In some embodiments, a third thickness h3 of the second insulating encapsulant 140b in the third region R3 is greater than a second thickness h2 of the first insulating encapsulant 140a in the second region R2. However, it is not limited and may depend on the standoffs of the first terminal 150a and the second terminal 150b. Therefore, in other embodiments, the third thickness h3 of the second insulating encapsulant 140b may be smaller than the second thickness h2 of the first insulating encapsulant 140a.

In some embodiments, a first level height difference dh1 between a bottom surface 170b of the bridge die 170 and a top surface 116at of the first redistribution structure 116a is smaller than a second level height difference dh2 between the bottom surface 170b of the bridge die 170 and a top surface 116bt of the second redistribution structure 116b. However, it is not limited and may depend on the standoffs of the first terminal 150a and the second terminal 150b. Therefore, in other embodiments, a first level height difference dh1 may be greater than a second level height difference dh2.

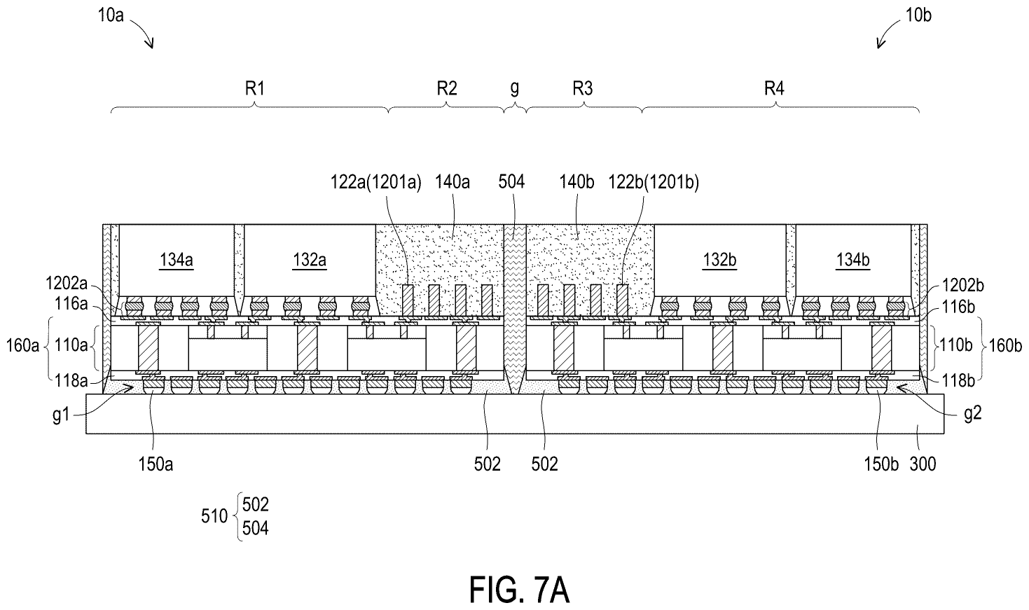

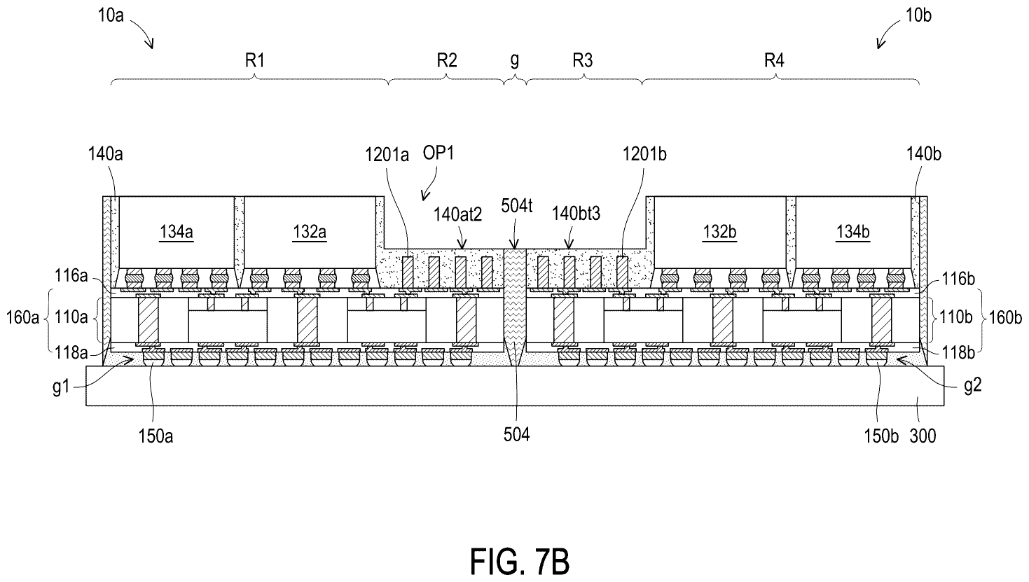

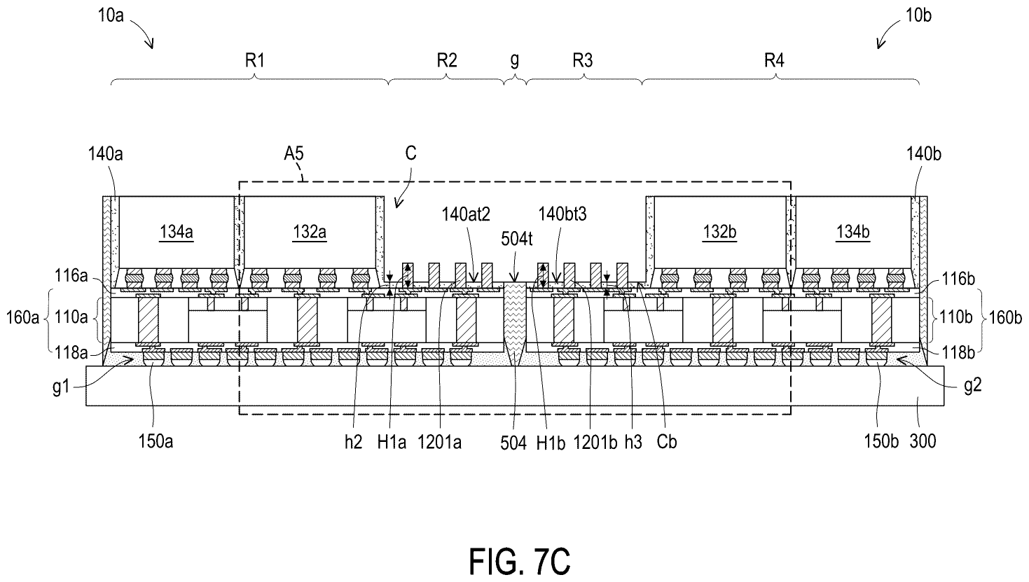

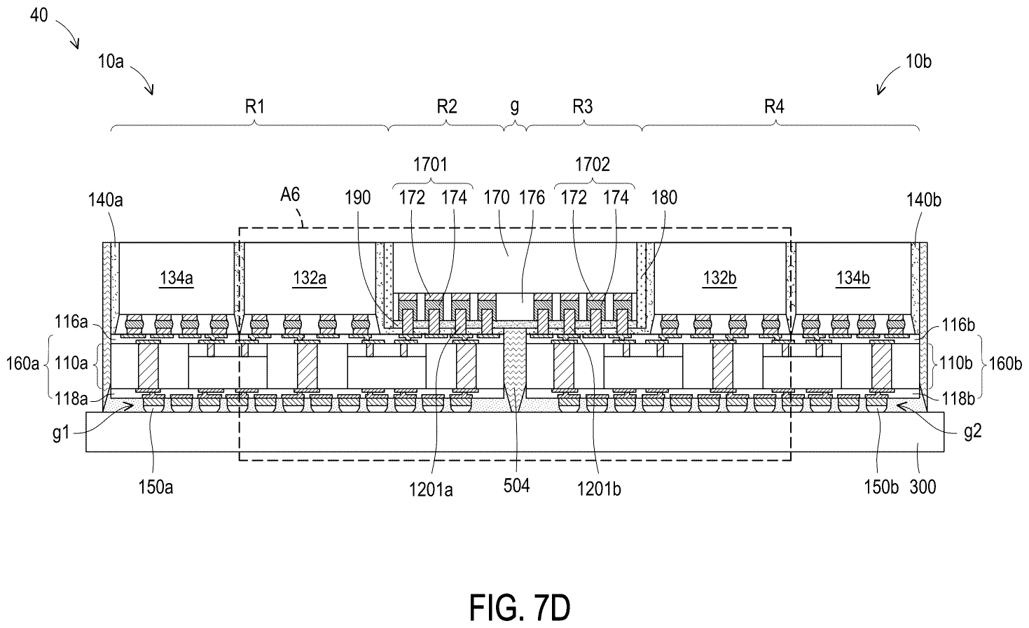

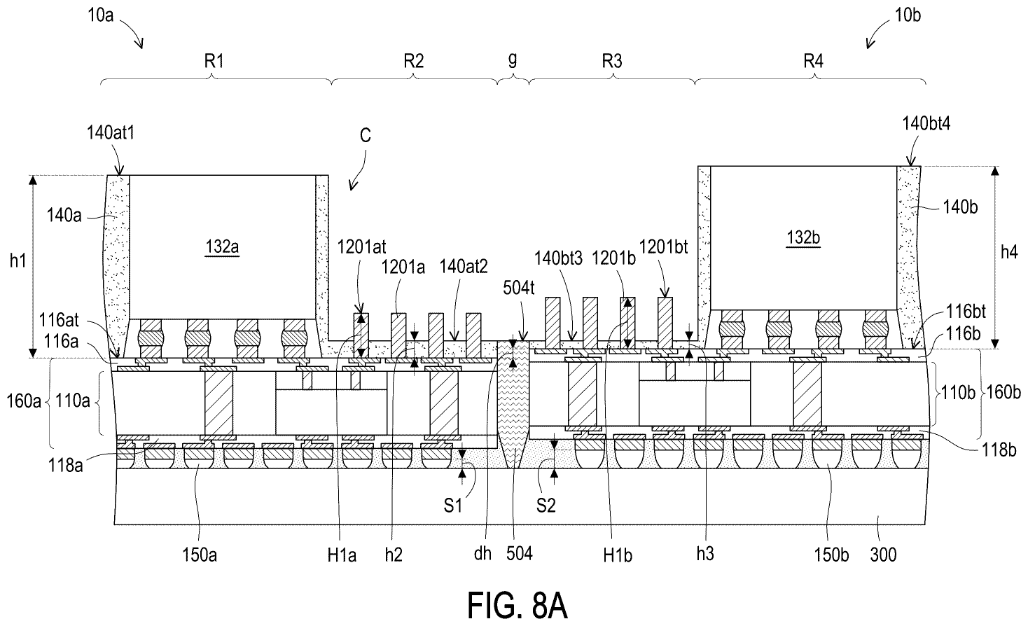

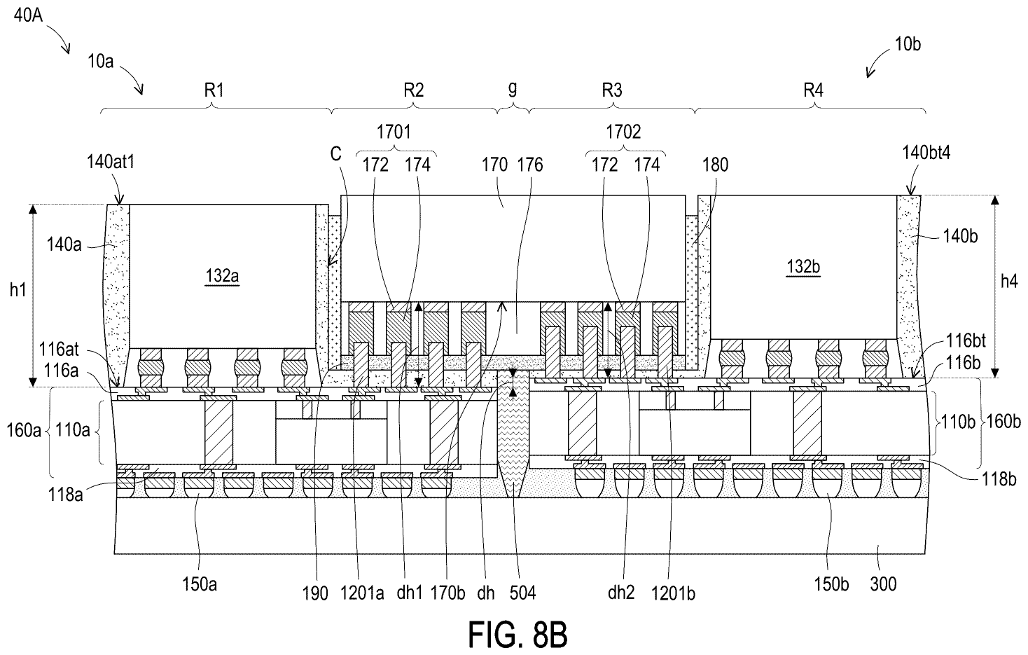

FIGS. 7A to 7D are schematic sectional views at various stages in a method of fabricating a semiconductor package 40 in accordance with some embodiments of the present disclosure. FIG. 8A is an enlargement view of an area A5 in an alternative embodiment of FIG. 7C in accordance with some embodiments of the present disclosure. FIG. 8B is an enlargement view of an area A6 in an alternative embodiment of FIG. 7D in accordance with some embodiments of the present disclosure. It should be noted herein that, in embodiment provided in FIGS. 7A to 7D and 8A to 8B, element numerals and partial content of the embodiments provided in FIGS. 2A to 2C, 5A to 5D and 6A to 6C are followed, the same or similar reference numerals being used to represent the same or similar elements, and description of the same technical content being omitted. For a description of an omitted part, reference may be made to the foregoing embodiment, and the descriptions thereof are omitted herein.

Referring to FIG. 7A, the first sub-package 10a and the second sub-package 10b are bonded to the substrate 300 and arranged side by side, which is similar to the process described in FIG. 5A, The insulating material 510 including the underfill 502 and the filling material 504 is formed on the substrate 300 to laterally encapsulate the first interposer 160a and the second interposer 160b. The forming of the insulating material 510 may be similar to the forming of the insulating material 510 described in FIG. 5A. In this embodiment, the first conductive connectors 1201a are conductive posts 122a without solder caps formed thereon and the second conductive connectors 1201b are conductive posts 122b without solder caps formed thereon. However, the embodiment is not limited thereto, and the first conductive connectors 1201a and the second conductive connectors 1201b may optionally include solder caps.

Referring to FIG. 7B, a first opening OP1 is formed to remove a portion of the first insulating encapsulant 140a in the second region R2, a portion of the second insulating encapsulant 140b in the third region R3 and a portion of the filling material 504 between the first sub-package 10a and the second sub-package 10b. The forming of the first opening OP1 may be similar to the forming of the first opening OP1 descried in FIG. 5B.

Referring to FIGS. 7C and 8A, an etching process is performed to the first insulating encapsulant 140a, the second insulating encapsulant 140b and the filling material 504 exposed by the first opening OP1 to form a cavity C exposing the first conductive connectors 1201a and the second conductive connectors 1201b. The etching process may be an anisotropic etching process, such as plasma etching process, reactive ion etching process or the like.

In some embodiments, the remaining first insulating encapsulant 140a in the second region R2 laterally encapsulates lower portions of the first conductive connectors 1201a, and upper portions of the first conductive connectors 1201a are exposed by the cavity C. Similarly, the remaining second insulating encapsulant 140b in the third region R3 laterally encapsulates lower portions of the second conductive connectors 1201b, and upper portions of the second conductive connectors 1201b are exposed by the cavity C. In other words, the first conductive connectors 1201a and the second conductive connectors 1201b may protrude from a top surface 140at2 of the first insulating encapsulant 140a or a top surface 140bt3 of the second insulating encapsulant 140b.

In some embodiments, a top surface 140at2 of the first insulating encapsulant 140a in the second region R2 substantially levels with a top surface 140bt3 of the second insulating encapsulant 140b in the third region R3 and a top surface 504t of the filling material 504.

In some embodiments, a height H1a of the first conductive connector 1201a and a height H1b of the second conductive connector 1201b are substantially the same, a thickness h2 of the first insulating encapsulant 140a in the second region R2 is smaller than the height H1a of the first conductive connector 1201a, and a thickness h3 of the second insulating encapsulant 140b in the third region R3 is smaller than the height H1b of the second conductive connector 1201b.

In an embodiments where the standoff S1 of the first conductive terminals 150a is substantially the same with the standoff S2 of the second conductive terminals 150b, the thickness h2 of the first insulating encapsulant 140a in the second region R2 may be substantially equal to the thickness h3 of the second insulating encapsulant 140b in the third region R3, as shown in FIG. 7C

In an embodiments where the standoff S1 of the first conductive terminals 150a is smaller than the standoff S2 of the second conductive terminals 150b, the top surface 116a t of the first redistribution structure 116a is lower than the top surface 116bt of the second redistribution structure 116b, and a thickness h2 of the first insulating encapsulant 140a in the second region R2 is greater than a thickness h3 of the second insulating encapsulant 140b in the third region R3, as shown in FIG. 8A. In such an embodiment, a level height difference dh between the top surface 116at of the first redistribution structure 116a and the top surface 116bt of the second redistribution structure 116b may be less than about 50 μm.

Referring to FIGS. 7D and 8B, a bridge die 170 is disposed in the cavity C to electrically connect with the first interposer 160a and the second interposer 160b by the first conductive connectors 1201a and the second conductive connectors 1201b. A dimension (such as a width or a length) of the bridge die 170 may be smaller than that of the cavity C.

The bridge die 170 includes a plurality of conductive connectors (including first conductive connectors 1701 and second conductive connectors 1702) for external connection and a passivation layer 176 laterally surrounds the first conductive connectors 1701 and the second conductive connectors 1702. The first conductive connectors 1701 and the second conductive connectors 1702 of the bridge die 170 may each include a conductive pillar 172 and a solder cap 174 formed on the conductive pillar 172.

In some embodiments, before disposing the bridge die 170 in the cavity C, a non-conductive film 190 is formed on the conductive connectors of the bridge die 170 (that is, first conductive connectors 1701 and second conductive connectors 1702). When disposing the bridge die 170 in the cavity C, a side of the bridge die 170 with the non-conductive film 190 formed thereon faces the exposed first conductive connectors 1201a and the second conductive connectors 1201b in the cavity C, and then the conductive connectors of the bridge die 170 (that is, first conductive connectors 1701 and second conductive connectors 1702) are bonded to the first conductive connectors 1201a of the first interposer 160a and the second conductive connectors s 1201b of the second interposer 160b by thermocompression. In this way, the non-conductive film 190 is disposed between the bridge die 170 and the first insulating encapsulant 140a, between the bridge die 170 and the second insulating encapsulant 140b, and between the bridge die 170 and the filling material 504. The first conductive connectors 1201a of the first interposer 160a and the second conductive connectors 1201b of the second interposer 160b may penetrate through the non-conductive film 190 and connect to the corresponding conductive connectors of the bridge die 170 (for example, first conductive connectors 1701 or second conductive connectors 1702).

In some embodiments, a portion of the first conductive connector 1201a of the first interposer 160a may be embedded in the solder cap 174 of the corresponding first conductive connector 1701 of the bridge die 170, and a portion of the second conductive connector 1201b of the second interposer 160b may be embedded in the solder cap 174 of the corresponding second conductive connector 1702 of the bridge die 170. In this way, the solder caps 172 and 174 may absorb or balance the level height difference (such as level height difference dh) or the standoff difference between the first terminals 150a and the second terminals 150b.

Still referring to FIGS. 7D and 8B, an underfill 180 is formed in the cavity C. The underfill 180 may be located in a gap between an inner sidewall of the first insulating encapsulant 140a in the first region R1 and a sidewall of the bridge die 170 as well as between an inner sidewall of the second insulating encapsulant 140b in the fourth region R4 and a sidewall of the bridge die 170. In some embodiments, the underfill 180 may further extend to cover a sidewall of the non-conductive film 190.

Based on the above, the fabrication of a semiconductor package 40 and/or a semiconductor package 40A is substantially completed.

Referring to FIG. 7D, the semiconductor package 40 is similar to the semiconductor package 20 in FIG. 2C, and the difference between the semiconductor package 40 to the semiconductor package 30 is that the semiconductor package 40 further includes a non-conductive film 190 disposed between the bridge die 170 and the first interposer 160a as well as between the bridge die 170 and the second interposer 160b. The first conductive connectors 1201a of the first interposer 160a and the second conductive connectors 1201b of the second interposer 160b penetrate through the non-conductive film 190.

In some embodiments, a tip of the first conductive connectors 1201a of the first interposer 160a or a tip of the second conductive connectors 1201b of the second interposer 160b is surrounded by a solder cap 174 of the corresponding conductive connector of the bridge die 170 (such as the first conductive connector 1701 or the second conductive connector 1702).

In some embodiments, the first insulating encapsulant 140a in the second region R2 is disposed between the non-conductive film 190 and the first redistribution structure 116a, and the second insulating encapsulant 140b in the third region R3 is disposed between the non-conductive film 190 and the second redistribution structure 116b. In other words, the first insulating encapsulant 140a encapsulates the dies 130a in the first region R1 and extends between the non-conductive film 190 and the first redistribution structure 116a in the second region R2. Similarly, the second insulating encapsulant 140b encapsulates the dies 130b in the fourth region R4 and extends between the non-conductive film 190 and the second redistribution structure 116b in the third region R3.

Referring to FIG. 8B, the semiconductor package 40A is similar to the semiconductor package 40 in FIG. 7D, and the difference between the semiconductor package 40A and the semiconductor package 40 is that the semiconductor package 40A has a level height difference dh between the top surface 116at of the first redistribution structure 116a and the top surface 116bt of the second redistribution structure 116b caused by the standoff difference between the first conductive terminals 150a of the first sub-package 10a and the second conductive terminals 150b of the second sub-package 10b while mounting the first sub-package 10a and the second sub-package 10b on the substrate 300. Specifically, in FIG. 8B, the standoff S1 of the first terminals 150a is smaller than the standoff S2 of the second terminals 150b, so that the top surface 116at of the first redistribution structure 116a is lower than the top surface 116bt of the second redistribution structure 116b. However, the embodiment is not limited thereto. In other embodiments, the standoff S1 of the first terminals 150a may be larger than the standoff S2 of the second terminals 150b, so that the top surface 116at of the first redistribution structure 116a may be higher than the top surface 116bt of the second redistribution structure 116b.

In some embodiments, a top surface 140at2 (labeled in FIG. 8A) of the first insulating encapsulant 140a in the second region R2 substantially levels with a top surface 140bt3 (labeled in FIG. 8A) of the second insulating encapsulant 140b in the third region R3, and a top surface 140at1 (labeled in FIG. 8A) of the first insulating encapsulant 140a in the first region R1 does not level with a top surface 140bt1 (labeled in FIG. 8A) of the second insulating encapsulant 140b in the fourth region R4. In such embodiment, a level height difference between the top surface 140at1 of the first insulating encapsulant 140a in the first region R1 and the top surface 140bt1 of the second insulating encapsulant 140b in the fourth region R4 may be similar to the level height difference dh.

In some embodiments, a third thickness h3 (labeled in FIG. 8A) of the second insulating encapsulant 140b in the third region R3 is smaller than a second thickness h2 (labeled in FIG. 8A) of the first insulating encapsulant 140a in the second region R2. However, it is not limited and may depend on the standoffs of the first terminal 150a and the second terminal 150b. Therefore, in other embodiments, the third thickness h3 of the second insulating encapsulant 140b in the third region R3 may be greater than the second thickness h2 of the first insulating encapsulant 140a in the second region R2.

In some embodiments, a first level height difference dh1 between a bottom surface 170b of the bridge die 170 and a top surface 116at of the first redistribution structure 116a is greater than a second level height difference dh2 between the bottom surface 170b of the bridge die 170 and a top surface 116bt of the second redistribution structure 116b. However, it is not limited and may depend on the standoffs of the first terminal 150a and the second terminal 150b. Therefore, in other embodiments, a first level height difference dh1 may be less than a second level height difference dh2.

Since the semiconductor package includes a bridge die connected between the first interposer and the second interposer, a large-sized interposer can be easily formed and jointed on the substrate, such that the wafer yield and utilization can be improved.

In accordance with some embodiments, a semiconductor package is described. The semiconductor package includes a substrate, a first interposer, a second interposer, a first die, a second die and a bridge die. The first interposer and the second interposer are arranged side by side over the substrate. The first die is disposed on the first interposer. The second die is disposed on the second interposer. The bridge die is disposed on and electrically connected between the first interposer and the second interposer. The first die and the second die are electrically connected to each other through the first interposer, the second interposer and the bridge die.

In accordance with another embodiment, a semiconductor package is described. The semiconductor package includes a substrate, a first sub-package on the substrate, a second sub-package arranged side by side with the first sub-package on the substrate and a bridge die. The first sub-package includes a first interposer having a first surface and a second surface opposite to the first surface, a first die disposed on the first surface of the first interposer, a first insulating encapsulant disposed on the first surface of the first interposer and encapsulating the first die and a first conductive terminal disposed between the second surface of the first interposer and the substrate. The second sub-package includes a second interposer having a third surface and a fourth surface opposite to the fourth surface, a second die disposed on the third surface of the second interposer, a second insulating encapsulant disposed on the third surface of the second interposer and encapsulating the second die and a second conductive terminal disposed between the fourth surface of the second interposer and the substrate. The bridge die is disposed over the first insulating encapsulant and the second insulating encapsulant, and is electrically connected with the first interposer and the second interposer. A standoff of the first conductive terminal is different from a standoff of the second conductive terminal.

In accordance with yet another embodiment of the disclosure, a method for forming a semiconductor package is described. The method at least includes the following steps. A first sub-package and a second sub-package are placed to a substrate. The first sub-package and the second sub-package are arranged side by side. The first sub-package comprises a first interposer, a first die disposed on the first interposer and a first insulating encapsulant disposed on the first interposer and encapsulating the first die. The second sub-package comprises a second interposer, a second die disposed on the second interposer and a second insulating encapsulant disposed on the second interposer and encapsulating the second die. An insulating material is filled into a gap between the first sub-package and the second sub-package. A cavity is formed to expose first conductive connectors of the first interposer and second conductive connectors of the second interposer. A bridge die is disposed in the cavity to electrically connect with the first interposer and the second interposer by the first conductive connectors and the second conductive connectors.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a substrate;
a first interposer and a second interposer arranged side by side over the substrate;
a first die disposed on the first interposer;
a second die disposed on the second interposer; and
a bridge die disposed on and electrically connected between the first interposer and the second interposer, wherein the first die and the second die are electrically connected to each other through the first interposer, the second interposer and the bridge die.

2. The semiconductor package of claim 1 further comprising an underfill, wherein the bridge die is located between the first die and the second die and overlaps a gap between the first interposer and the second interposer and the gap is filled with the underfill.

3. The semiconductor package of claim 1,
wherein the first interposer comprises:
a first interposer substrate;
a first redistribution structure disposed over the first interposer substrate; and
first conductive connectors disposed on the first redistribution structure and electrically connected to the bridge die, and
wherein the second interposer comprises:
a second interposer substrate;
a second redistribution structure disposed over the second interposer substrate; and
second conductive connectors disposed on the second redistribution structure and electrically connected to the bridge die, wherein a top surface of the first redistribution structure is lower than or higher than a top surface of the second redistribution structure.

4. The semiconductor package of claim 3, wherein a level height difference between the top surface of the first redistribution structure and the top surface of the second redistribution structure is less than about 50 μm.

5. The semiconductor package of claim 3, wherein a first level height difference between a bottom surface of the bridge die and the top surface of the first redistribution structure is different from a second level height difference between the bottom surface of the bridge die and the top surface of the second redistribution structure.

6. The semiconductor package of claim 3 further comprising a non-conductive film disposed between the bridge die and the first interposer as well as between the bridge die and the second interposer, wherein the first conductive connectors and the second conductive connectors penetrate through the non-conductive film.

7. The semiconductor package of claim 6 further comprising a first encapsulant encapsulating the first die and a second encapsulant encapsulating the second die, wherein the first encapsulant further extends between the non-conductive film and the first redistribution structure, and the second encapsulant further extends between the non-conductive film and the second redistribution structure.

8. The semiconductor package of claim 3, wherein the first interposer further comprises third conductive connectors disposed on the first redistribution structure and electrically connected to the first die, wherein a height of the first conductive connectors is greater than a height of the third conductive connectors.

9. A semiconductor package, comprising:
a substrate;
a first sub-package on the substrate, and the first sub-package comprising:
a first interposer having a first surface and a second surface opposite to the first surface;
a first die disposed on the first surface of the first interposer;
a first encapsulant disposed on the first surface of the first interposer and encapsulating the first die; and
a first conductive terminal disposed between the second surface of the first interposer and the substrate;
a second sub-package arranged side by side with the first sub-package on the substrate, and the second sub-package comprising:
a second interposer having a third surface and a fourth surface opposite to the fourth surface;
a second die disposed on the third surface of the second interposer;
a second encapsulant disposed on the third surface of the second interposer and encapsulating the second die; and
a second conductive terminal disposed between the fourth surface of the second interposer and the substrate; and
a bridge die disposed over the first encapsulant and the second encapsulant, wherein the bridge die is electrically connected with the first interposer and the second interposer,
wherein a standoff of the first conductive terminal is different from a standoff of the second conductive terminal.

10. The semiconductor package of claim 9, wherein the first sub-package has a first region and a second region, the first die is located in the first region and a portion of the bridge die is located in the second region, the first encapsulant has a first thickness in the first region and a second thickness in the second region, and the first thickness is greater than the second thickness.

11. The semiconductor package of claim 10, wherein the second sub-package has a third region and a fourth region, the second die is located in the fourth region and another portion of the bridge die is located in the third region, the second encapsulant has a third thickness in the third region and the third thickness is different from the second thickness.

12. The semiconductor package of claim 11, wherein a top surface of the first encapsulant in the second region substantially levels with a top surface of the second encapsulant in the third region, and a top surface of the first encapsulant in the first region does not level with a top surface of the second encapsulant in the fourth region.

13. The semiconductor package of claim 9 further comprising a filling material disposed between the first interposer and the second interposer as well as between the first encapsulant and the second encapsulant, wherein the bridge die comprises a first conductive connector partially disposed in the first encapsulant and a second conductive connector partially disposed in the second encapsulant.

14. The semiconductor package of claim 13, wherein the filling material further extends to a first gap between the second surface of the first interposer and the substrate and a second gap between the fourth surface of the second interposer and the substrate.

15. A method for forming a semiconductor package, comprising:
placing a first sub-package and a second sub-package to a substrate, wherein the first sub-package and the second sub-package are arranged side by side, the first sub-package comprises a first interposer, a first die disposed on the first interposer and a first encapsulant disposed on the first interposer and encapsulating the first die, and the second sub-package comprises a second interposer, a second die disposed on the second interposer and a second encapsulant disposed on the second interposer and encapsulating the second die;
filling an insulating material into a gap between the first sub-package and the second sub-package;
forming a cavity to expose first conductive connectors of the first interposer and second conductive connectors of the second interposer; and
disposing a bridge die in the cavity to electrically connect with the first interposer and the second interposer by the first conductive connectors and the second conductive connectors.

16. The method of claim 15, wherein forming the cavity comprises:
removing a portion of the first encapsulant, a portion of the second encapsulant and a portion of the insulating material until the first conductive connectors and the second conductive connectors are exposed, wherein a bottom surface of the cavity levels with a top surface of the first conductive connectors and a top surface of the second conductive connectors.

17. The method of claim 16, wherein a portion of the first conductive connectors or a portion of the second conductive connectors is removed during forming the cavity, and a height of the first conductive connectors is different from a height of the second conductive connectors.

18. The method of claim 15, wherein forming the cavity comprises:
removing a portion of the first encapsulant, a portion of the second encapsulant and a portion of the insulating material to form a first opening; and
forming second openings in the first encapsulant and the second encapsulant exposed by the first opening, wherein the second openings expose the first conductive connectors and the second conductive connectors.

19. The method of claim 18, further comprising:
bonding conductive connectors of the bridge die to the first conductive connectors and the second conductive connectors in the second openings.

20. The method of claim 15, further comprising:
forming a non-conductive film on conductive connectors of the bridge die; and
bonding the conductive connectors of the bridge die to the first conductive connectors of the first interposer and the second conductive connectors of the second interposer by thermocompression.
